(19) United States
(12) Patent Application Publication
(10) Pub. No.: US 2025/0234618 A1
(43) Pub. Date: Jul. 17, 2025

(54) INTEGRATED CIRCUIT DEVICE WITH A POWER DELIVERY NETWORK

(71) Applicant: SAMSUNG ELECTRONICS CO., LTD., SUWON-SI (KR)

(72) Inventors: Seowoo NAM, Suwon-si (KR); Heonjong SHIN, Suwon-si (KR); Sanghee LEE, Suwon-si (KR); Jaeran JANG, Suwon-si (KR)

(21) Appl. No.: 19/013,089

(22) Filed: Jan. 8, 2025

(30) Foreign Application Priority Data
Jan. 16, 2024 (KR) 10-2024-0006805

(51) Int. Cl. H10D 64/23; H10D 30/00; H10D 30/43; H10D 62/13; H10D 84/83

(52) U.S. Cl. CPC H10D 64/251; H10D 30/43; H10D 30/502; H10D 62/151; H10D 84/832

(57) ABSTRACT

An integrated circuit device includes: a rear insulating layer; a nanosheet stacked structure arranged on the rear insulating layer and including a plurality of nanosheets; a pair of source/drain regions positioned on sides of the nanosheet stacked structure in a first horizontal direction; a gate electrode extending in a second horizontal direction intersecting the first horizontal direction, on the nanosheet stacked structure; a contact plug connected to at least one of the pair of source/drain regions; a rear contact plug passing through the rear insulating layer and connected to at least one of the pair of source/drain regions; and a spacer layer including a contact spacer layer surrounding part of a side surface of the rear contact plug.

### CROSS-REFERENCE TO RELATED APPLICATION

This application claims priority under 35 U.S.C. § 119 to Korean Patent Application No. 10-2024-0006805, filed on Jan. 16, 2024, in the Korean Intellectual Property Office, the disclosure of which is incorporated by reference herein in its entirety.

### TECHNICAL FIELD

The present inventive concept relates to an integrated circuit device, and more particularly, to an integrated circuit device with a power delivery network (PDN).

### DISCUSSION OF THE RELATED ART

With the development of electronic technology, down-scaling of integrated circuit devices is rapidly progressing. To efficiently transmit power to highly-integrated circuit devices, integrated circuit devices with PDNs are currently under development.

### SUMMARY

According to embodiments of the present inventive concept, an integrated circuit device includes: a rear insulating layer; a nanosheet stacked structure arranged on the rear insulating layer and including a plurality of nanosheets; a pair of source/drain regions positioned on sides of the nanosheet stacked structure in a first horizontal direction; a gate electrode extending in a second horizontal direction intersecting the first horizontal direction, on the nanosheet stacked structure; a contact plug connected to at least one of the pair of source/drain regions; a rear contact plug passing through the rear insulating layer and connected to at least one of the pair of source/drain regions; and a spacer layer including a contact spacer layer surrounding part of a side surface of the rear contact plug.

According to embodiments of the present inventive concept, an integrated circuit device includes: a nanosheet stacked structure including a plurality of nanosheets; a pair of source/drain regions connected to ends of each of the plurality of nanosheets in a first horizontal direction; a gate electrode extending in a second horizontal direction intersecting the first horizontal direction, on the nanosheet stacked structure; an inter-gate insulating layer at least partially surrounding the gate electrode and the pair of source/drain regions; a contact plug connected to one of the pair of source/drain regions through the inter-gate insulating layer; an etch stop layer covering surfaces of the pair of source/drain regions and a bottom surface of the inter-gate insulating layer; a cover insulating layer covering the etch stop layer and the inter-gate insulating layer; a rear insulating layer covering the cover insulating layer; a rear contact plug passing through the rear insulating layer and the cover insulating layer and connected to the other of the pair of source/drain regions; and a spacer layer including a contact spacer layer that surrounds part of a side surface of the rear contact plug and is located between the cover insulating layer and the rear contact plug.

According to embodiments of the present inventive concept, an integrated circuit device includes: a nanosheet stacked structure including a plurality of nanosheets; a pair of source/drain regions including a source region and a drain region, wherein the source region and the drain region are connected to ends of the plurality of nanosheets in a first horizontal direction; a gate electrode extending in a second horizontal direction intersecting the first horizontal direction, on the nanosheet stacked structure; an inter-gate insulating layer at least partially surrounding the gate electrode and the pair of source/drain regions; an etch stop layer covering surfaces of the pair of source/drain regions and a bottom surface of the inter-gate insulating layer; a cover insulating layer covering the etch stop layer and the inter-gate insulating layer; a rear insulating layer disposed below the cover insulating layer; a rear contact plug passing through the rear insulating layer and the cover insulating layer and connected to the source region; a contact plug passing through the inter-gate insulating layer and the etch stop layer and connected to the drain region; a placeholder structure passing through the cover insulating layer and connected to the drain region; and a spacer layer including a contact spacer layer and a placeholder spacer layer, wherein the contact spacer layer surrounds part of a side surface of the rear contact plug and is located between the cover insulating layer and the rear contact plug, and the placeholder spacer layer surrounds part of a side surface of the placeholder structure and is located between the cover insulating layer and the placeholder structure.

### BRIEF DESCRIPTION OF THE DRAWINGS

The above and other aspects of the present inventive concept will become more apparent by describing in detail embodiments thereof, with reference to the accompanying drawings, in which:

FIG. 1 is a layout of an integrated circuit device according to embodiments;

FIGS. 2A, 2B, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, and 25B are cross-sectional views illustrating a method of manufacturing an integrated circuit device according to embodiments of the present inventive concept;

FIGS. 26A and 26B are cross-sectional views illustrating an integrated circuit device according to embodiments of the present inventive concept;

FIGS. 27A, 27B, 28A, 28B, 29A, and 29B are cross-sectional views illustrating a method of manufacturing an integrated circuit device according to embodiments of the present inventive concept;

FIGS. 30A and 30B are cross-sectional views illustrating an integrated circuit device according to embodiments of the present inventive concept;

FIGS. 31A and 31B are cross-sectional views illustrating a method of manufacturing an integrated circuit device according to embodiments of the present inventive concept;

FIGS. 32A and 32B are cross-sectional views illustrating an integrated circuit device according to embodiments of the present inventive concept;

FIGS. 33A and 33B are cross-sectional views illustrating a method of manufacturing an integrated circuit device according to embodiments of the present inventive concept; and

FIGS. 34A and 34B are cross-sectional views illustrating an integrated circuit device according to embodiments of the present inventive concept.

### DETAILED DESCRIPTION OF THE EMBODIMENTS

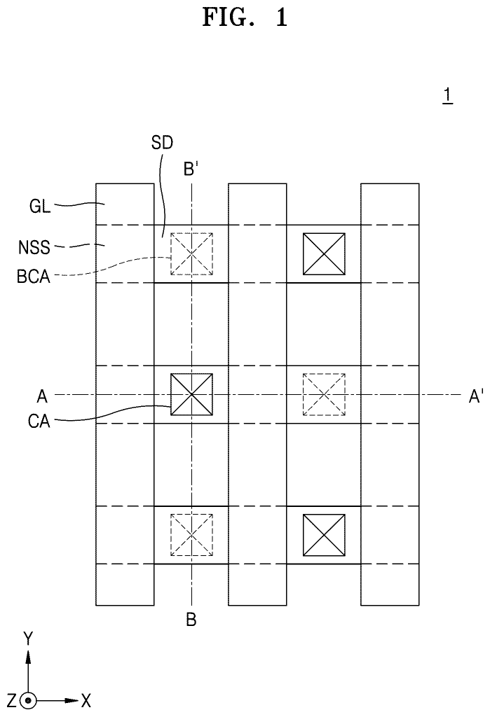

FIG. 1 is a layout of an integrated circuit device 1 according to embodiments of the embodiments of the present inventive concept.

Referring to FIG. 1, the integrated circuit device 1 includes a plurality of nanosheet stacked structures NSS, a plurality of gate electrodes GL, and a plurality of source/drain regions SD. The plurality of nanosheet stacked structures NSS may be arranged in rows and columns in a first horizontal direction (an X direction) and a second horizontal direction (a Y direction). For example, the plurality of nanosheet stacked structures NSS may extend in the first horizontal direction (the X direction) and may be arranged in the second horizontal direction (the Y direction). The first horizontal direction (the X direction) and the second horizontal direction (the Y direction) may be orthogonal to each other. The plurality of gate electrodes GL may be spaced apart from one another in the first horizontal direction (the X direction) and may extend in the second horizontal direction (the Y direction).

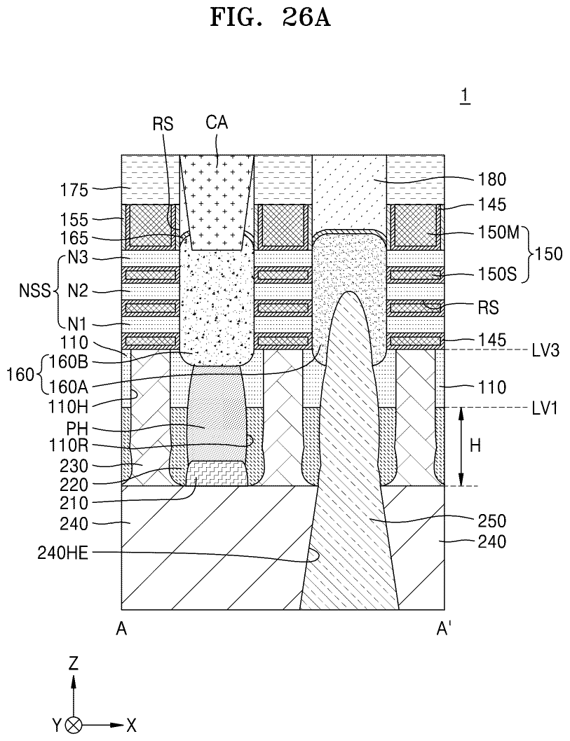

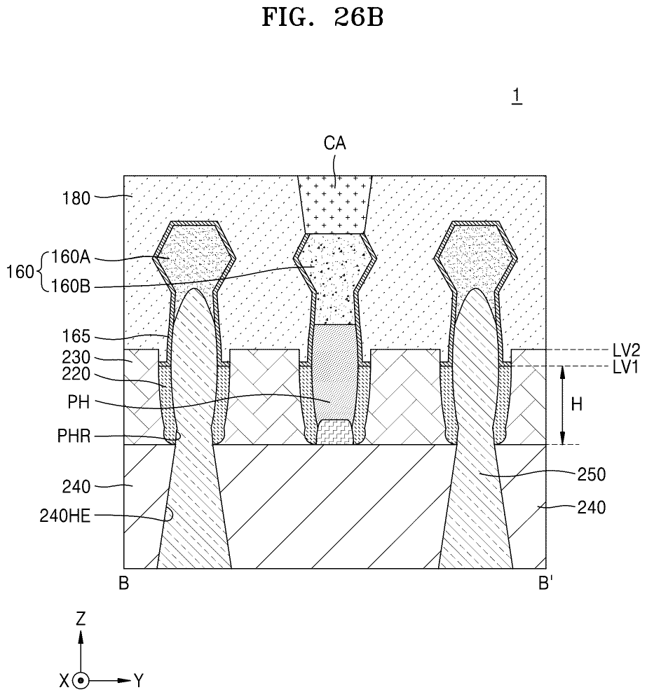

Each of the plurality of nanosheet stacked structures NSS may include a plurality of nanosheets N1, N2, and N3 (refer to FIG. 26A) stacked on each other while being spaced apart from one another in a vertical direction (a Z direction). In the first horizontal direction (the X direction), the source/drain regions SD may be arranged on both sides of each of the plurality of nanosheet stacked structures NSS. The source/drain region SD may be connected to each of the plurality of nanosheets N1, N2, and N3 (refer to FIG. 26A) that are included in each of the plurality of nanosheet stacked structures NSS adjacent to one another in the first horizontal direction (the X direction). In embodiments of the present inventive concept, the source/drain region SD may be interposed between a pair of nanosheet stacked structures NSS that are adjacent to each other in the first horizontal direction (the X direction) among the plurality of nanosheet stacked structures NSS. For example, the plurality of nanosheet stacked structures NSS and the plurality of source/drain regions SD may be alternately arranged in the first horizontal direction (the X direction).

A contact plug CA may be connected above some of the plurality of source/drain regions SD, and a rear contact plug BCA may be connected below others of the plurality of source/drain regions SD. In embodiments of the present inventive concept, in the first horizontal direction (the X direction), the contact plug CA may be connected to the source/drain region SD arranged on one side of the plurality of nanosheet stacked structures NSS and the rear contact plug BCA may be connected to the source/drain region SD arranged on the other side of the plurality of nanosheet stacked structures NSS. In embodiments of the present inventive concept, the contact plug CA may be connected above some of the plurality of source/drain regions SD, and the rear contact plug BCA may be connected below the remaining source/drain regions SD. However, the present inventive concept is not limited thereto. For example, each of the contact plug CA and the rear contact plug BCA may be connected to at least one of the plurality of source/drain regions SD.

The integrated circuit device 1 may include a plurality of logic cells. The logic cells may be configured in various ways, including a plurality of circuit elements such as transistors and resistors. The logic cells may configure, for example, AND, NAND, OR, NOR, exclusive OR (XOR), exclusive NOR (XNOR), an inverter (INV), an adder (ADD), a buffer (BUF), a delay (DLY), a filter (FIL), a multiplexer (MXT/MXIT), OR/AND/INVERTER (OAI), AND/OR (AO), AND/OR/INVERTER (AOI), a D flip-flop, a reset flip-flop, a master-slave flip-flop, or a latch, and the logic cells may configure standard cells performing logical functions.

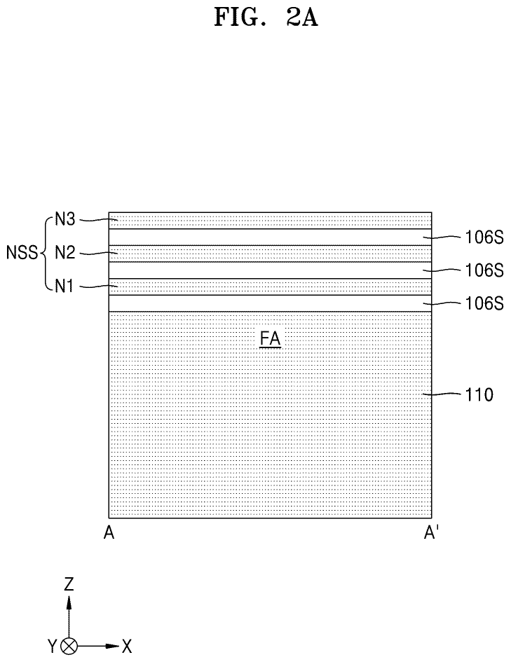

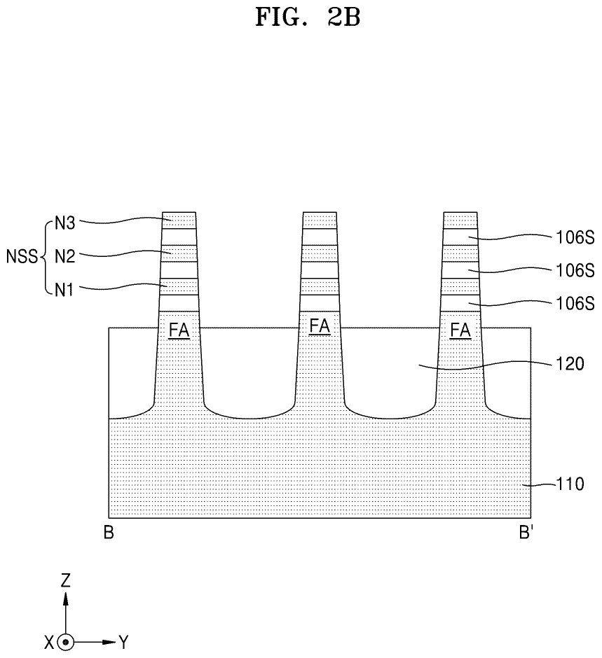

FIGS. 2A to 25B are cross-sectional views illustrating a method of manufacturing an integrated circuit device according to embodiments of the present inventive concept. Specifically, FIGS. 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, and 25A are cross-sectional views taken along the line A-A′ in FIG. 1, and FIGS. 2B, 3B, 4B, 5B, 6B, 7B, 8B, 9B, 10B, 11B, 12B, 13B, 14B, 15B, 16B, 17B, 18B, 19B, 20B, 21B, 22B, 23B, 24B, and 25B are cross-sectional views taken along the line B-B′ in FIG. 1.

Referring to FIGS. 2A and 2B together, a plurality of sacrificial semiconductor layers 106S and a plurality of nanosheet semiconductor layers are alternately stacked on the substrate 110 one by one. The plurality of sacrificial semiconductor layers 106S and the plurality of nanosheet semiconductor layers may include different semiconductor materials. In embodiments of the present inventive concept, the plurality of nanosheet semiconductor layers may include a single material. In embodiments of the present inventive concept, the plurality of nanosheet semiconductor layers may include the same material as that of the substrate 110. In embodiments of the present inventive concept, the plurality of sacrificial semiconductor layers 106S may include SiGe, and the plurality of nanosheet semiconductor layers may include Si. However, the present inventive concept is not limited thereto.

The plurality of sacrificial semiconductor layers 106S may all be formed to the same thickness. However, the present inventive concept is not limited thereto. In embodiments of the present inventive concept, among the plurality of sacrificial semiconductor layers 106S, a thickness of the sacrificial semiconductor layer 106S that is closest to the substrate 110 may be greater than a thickness of each of the remaining sacrificial semiconductor layers 106S.

The substrate 110 may include a semiconductor material such as Si or Ge, or a compound semiconductor material such as SiGe, SiC, GaAs, InAs, or InP. In embodiments of the present inventive concept, the substrate 110 may include at least one of a group III-V material and a group IV material. The group III-V material may be a binary, ternary, or quaternary compound including at least one group III element and at least one group V element. In embodiments of the present inventive concept, when an n-type metal oxide semiconductor (NMOS) transistor is formed on a part of the substrate 110, a part of the substrate 110 may include any one of the group III-V materials illustrated above. In embodiments of the present inventive concept, when a p-type metal oxide semiconductor (PMOS) transistor is formed on a part of the substrate 110, a part of the substrate 110 may include Ge. In an example, the substrate 110 may have a semiconductor on insulator (SOI) structure. The substrate 110 may include a conductive region, for example, an impurity-doped well or an impurity-doped structure.

The stacked structure of the plurality of sacrificial semiconductor layers 106S and the plurality of nanosheet semiconductor layers and a part of the substrate 110 are etched to form a plurality of fin-type active regions FA in the substrate 110. The plurality of fin-type active regions FA may protrude upward from a main surface of the substrate 110 in the vertical direction (the Z direction). In embodiments of the present inventive concept, the plurality of fin-type active regions FA may extend in the first horizontal direction (the X direction). In embodiments of the present inventive concept, each of the plurality of fin-type active regions FA may have the same width in the second horizontal direction (the Y direction) orthogonal to the first horizontal direction (the X direction).

A surface of the substrate 110, on which the plurality of fin-type active regions FA are formed, that is, an active surface of the substrate 110 may be referred to as a front surface. In the current specification, the front surface of the substrate 110 may be a surface facing upward in FIGS. 2A to 34B. For example, the front surface of the substrate 110 may be referred to as a top surface of the substrate 110. In the current specification, a surface opposite to the front surface of the substrate 110, that is, an inactive surface of the substrate 110 may be referred to as a rear surface of the substrate 110. In the current specification, the rear surface of the substrate 110 may be a surface facing downward in FIGS. 2A to 34B. For example, the rear surface of the substrate 110 may be referred to as a bottom surface of the substrate 110.

The nanosheet stacked structure NSS that is the stacked structure of the plurality of sacrificial semiconductor layers 106S and the plurality of nanosheets N1, N2, and N3 may be arranged on each of the plurality of fin-type active regions FA. The plurality of nanosheet stacked structures NSS may be formed by removing parts of the plurality of nanosheet semiconductor layers by etching. The plurality of nanosheet stacked structures NSS may be arranged in rows and columns in the first horizontal direction (the X direction) and the second horizontal direction (the Y direction). The plurality of nanosheet stacked structures NSS may be arranged with a pitch of about 30 nm to about 50 nm in the first horizontal direction (the X direction).

A device isolation layer 120 is formed to fill at least parts of spaces among the plurality of fin-type active regions FA. In embodiments of the present inventive concept, the device isolation layer 120 may fill lower portions of the spaces among the plurality of fin-type active regions FA, and the plurality of fin-type active regions FA may protrude in the vertical direction (the Z direction) beyond a top surface of the device isolation layer 120. The device isolation layer 120 may include, for example, a material including at least one of a silicon oxide layer, a silicon nitride layer, and a silicon oxynitride layer. The plurality of nanosheet stacked structures NSS may be arranged in columns with a pitch of about 30 nm to about 50 nm in the first horizontal direction (the X direction).

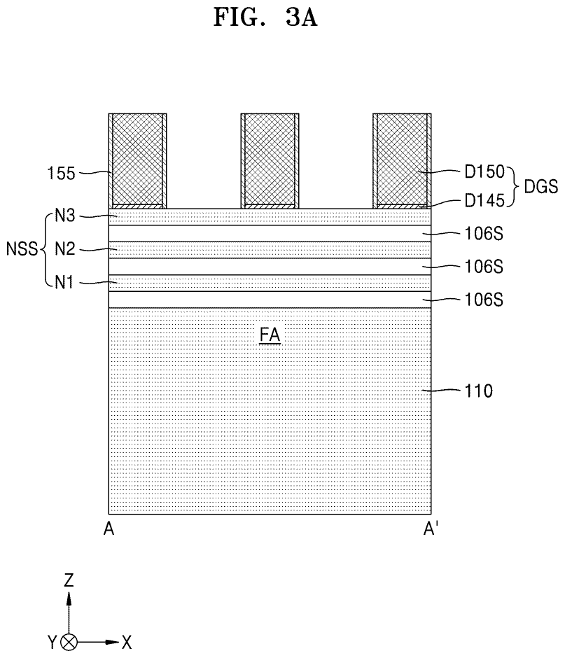

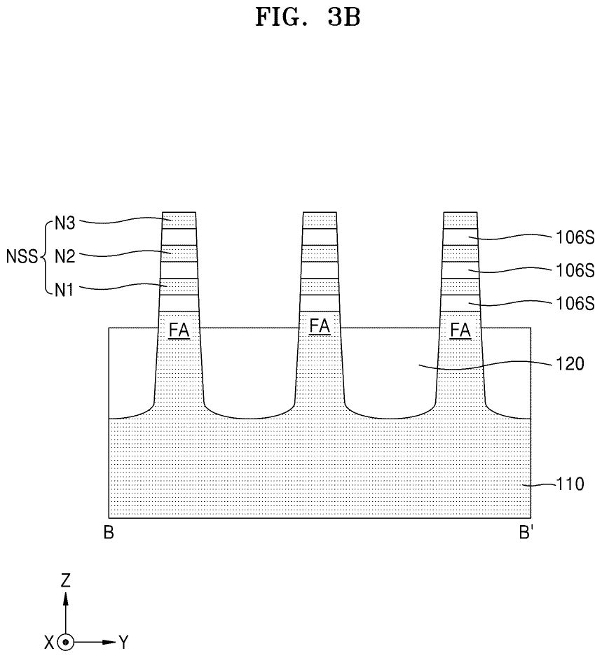

Referring to FIGS. 3A and 3B together, a plurality of dummy gate structures DGS with a stacked structure of a plurality of dummy insulating layers D145 extending to intersect at least parts of the plurality of fin-type active regions FA and a plurality of dummy gate electrodes D150 are formed on the plurality of fin-type active regions FA in which the plurality of nanosheet stacked structures NSS and the plurality of sacrificial semiconductor layers 106S are formed. The plurality of dummy gate structures DGS may be parallel to one another and spaced apart from one another in the first horizontal direction (the X direction) and may extend in the second horizontal direction (the Y direction).

The dummy insulating layer D145 and the dummy gate electrode D150 are sequentially formed to cover exposed surfaces of the plurality of nanosheet stacked structures NSS and the plurality of sacrificial semiconductor layers 106S covering the plurality of fin-type active regions FA, exposed surfaces of the plurality of fin-type active regions FA, and the top surface of the device isolation layer 120, and then patterned to form the dummy gate structure DGS so that only necessary portions of the dummy insulating layer D145 and the dummy gate electrode D150 remain, and a gate spacer 155 covering side surfaces of each of the plurality of dummy gate structures DGS is formed. The dummy insulating layer D145 may include oxide and the dummy gate electrode D150 may include a semiconductor material. However, the present inventive concept is not limited thereto. In embodiments of the present inventive concept, the dummy insulating layer D145 may include silicon oxide, and the dummy gate electrode D150 may include polysilicon. The gate spacer 155 may include silicon nitride. However, present the inventive concept is not limited thereto. The gate spacer 155 may include a single layer or a stacked structure of two or more layers.

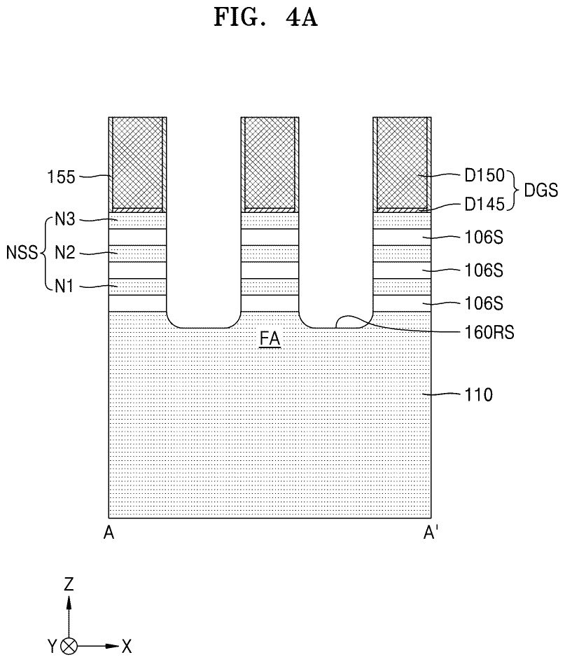

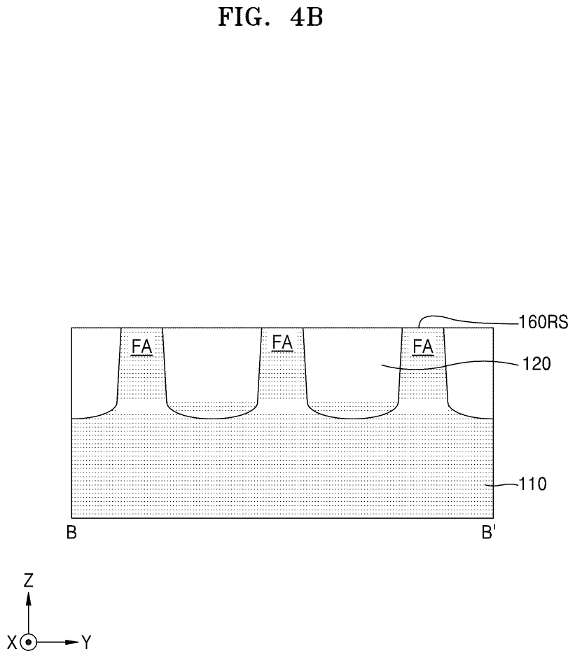

Referring to FIGS. 4A and 4B together, a plurality of source/drain recesses 160RS may be formed to expose portions of the plurality of fin-type active regions FA each arranged between a pair of dummy gate structures DGS that are adjacent to each other in the first horizontal direction (the X direction) by removing parts of the plurality of nanosheet stacked structures NSS and parts of the plurality of sacrificial semiconductor layers 106S. In embodiments of the present inventive concept, in the process of forming the plurality of source/drain recesses 160RS, upper portions of the plurality of fin-type active regions FA may be partially removed.

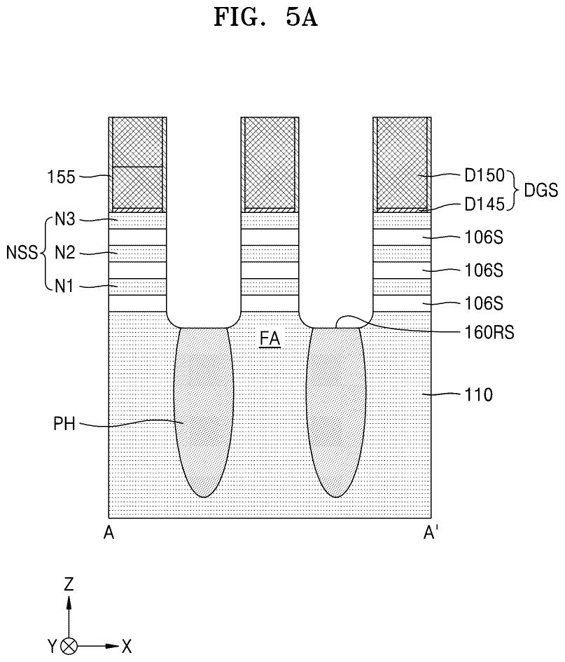

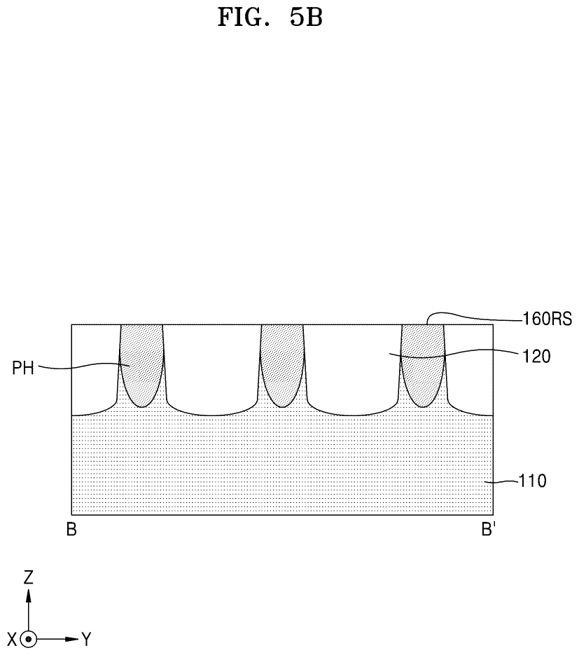

Referring to FIGS. 5A and 5B together, after removing parts of the portions of the plurality of fin-type active regions FA exposed at bottom surfaces of the plurality of source/drain recesses 160RS, the placeholder structure PH is formed in the spaces from which parts of the exposed portions of the plurality of fin-type active regions FA are removed. In embodiments of the present inventive concept, the placeholder structure PH may include a semiconductor material. For example, the placeholder structure PH may include a compound semiconductor such as SiGe. The placeholder structure PH may have a horizontal width of about 7 nm to about 20 nm. The placeholder structure PH may have a height of about 30 nm to about 70 nm.

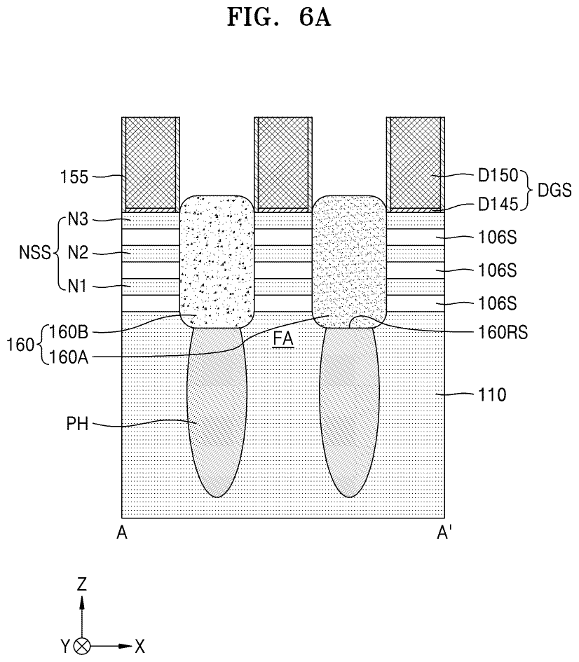

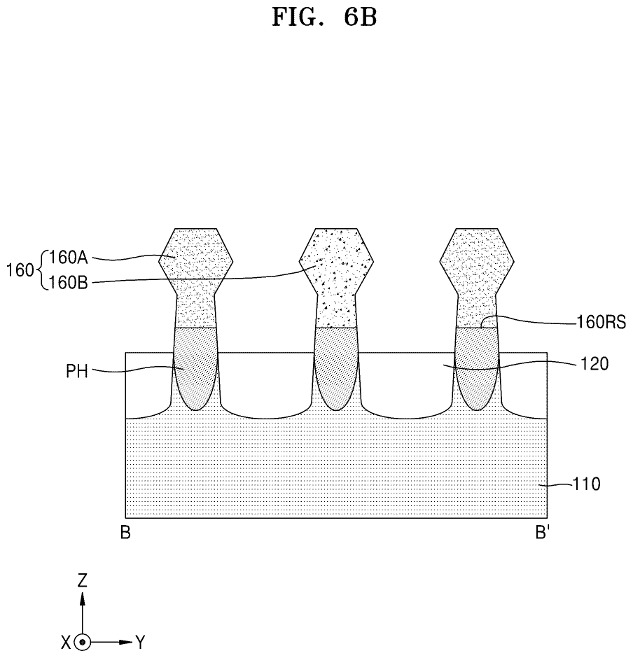

Referring to FIGS. 6A and 6B together, the plurality of source/drain regions 160 are formed to fill parts of the plurality of source/drain recesses 160RS by epitaxially growing a semiconductor material from both exposed side surfaces of each of the plurality of nanosheets N1, N2, and N3 and the exposed surface of the fin-type active region FA. In embodiments of the present inventive concept, when the upper portions of the plurality of fin-type active regions FA are partially removed in the process of forming the plurality of source/drain recesses 160RS, the plurality of source/drain regions 160 may be formed to extend inward from top surfaces of the plurality of fin-type active regions FA. In embodiments of the present inventive concept, the source/drain region 160 may be formed such that a top surface thereof has an angular shape, that is, a facet. The source/drain region 160 may have a horizontal width of about 15 nm to about 30 nm.

Because the plurality of placeholder structures PH are formed after removing parts of the portions of the plurality of fin-type active regions FA that are exposed at the bottom surfaces of the plurality of source/drain recesses 160RS, and the plurality of source/drain regions 160 are formed to fill parts of the plurality of source/drain recesses 160RS, each of the plurality of source/drain regions 160 may be aligned in the vertical direction (the Z direction) with a corresponding placeholder structure PH of the plurality of corresponding placeholder structures PH.

In embodiments of the present inventive concept, some and other parts of the plurality of source/drain regions 160 may include different materials, and some and other parts of the plurality of source/drain regions 160 including different materials may be formed by performing separate epitaxial growth processes, respectively. For example, some of the plurality of source/drain regions 160 may include Ge. In embodiments of the present inventive concept, some of the plurality of source/drain regions 160 may have a multilayer structure of a semiconductor material including Si and a semiconductor material including Ge. For example, others of the plurality of source/drain regions 160 may include Si but not Ge. In embodiments of the present inventive concept, others of the plurality of source/drain regions 160 may have a multilayer structure of a semiconductor material including Si, a semiconductor material such as Si, or a compound semiconductor material such as SiC.

In embodiments of the present inventive concept, the source/drain region 160 in the case of forming the NMOS transistor and the source/drain region 160 in the case of forming the PMOS transistor may include different materials from each other, and may be formed by performing separate epitaxial growth processes.

Each of the plurality of source/drain regions 160 may include a source region 160A and a drain region 160B. In embodiments of the present inventive concept, the source region 160A and the drain region 160B may be alternately arranged in the first horizontal direction (the X direction). The source region 160A and the drain region 160B may be connected to ends of each of the plurality of nanosheets N1, N2, and N3 in the first horizontal direction (the X direction). For example, the source region 160A may be connected to one end of each of the plurality of nanosheets N1, N2, and N3, and the drain region 160B may be connected to the other end (e.g., an opposing end) of each of the plurality of nanosheets N1, N2, and N3.

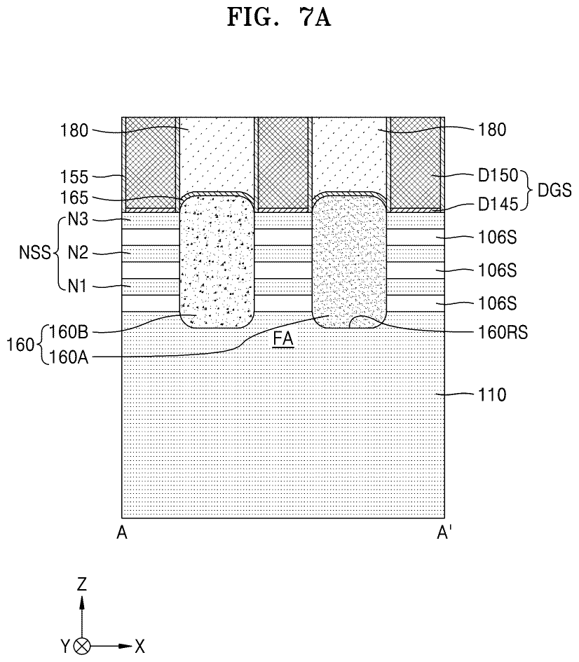

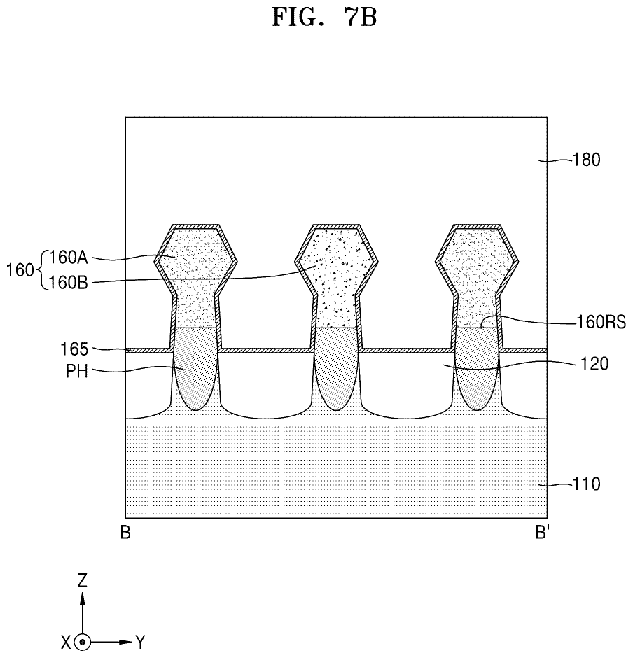

Referring to FIGS. 7A and 7B together, after forming the plurality of source/drain regions 160, an etch stop layer 165 is formed to cover surfaces of the plurality of source/drain regions 160. The etch stop layer 165 may conformally cover the surfaces of the plurality of source/drain regions 160 and the top surface of the device isolation layer 120. For example, the etch stop layer 165 may include nitride. In embodiments of the present inventive concept, the etch stop layer 165 may include silicon nitride.

An inter-gate insulating layer 180 is formed to cover the etch stop layer 165 and fill spaces among the plurality of dummy gate structures DGS. The inter-gate insulating layer 180 may fill the spaces among the plurality of dummy gate structures DGS and surround the plurality of source/drain regions 160. For example, the inter-gate insulating layer 180 fills spaces that are between neighboring dummy gate structures DGS. The inter-gate insulating layer 180 may include a silicon oxide layer. In embodiments of the present inventive concept, the inter-gate insulating layer 180 may have a stacked structure of two or more layers including a first layer including silicon nitride and a second layer including silicon oxide. The etch stop layer 165 may be interposed between the source/drain regions 160 and the inter-gate insulating layer 180.

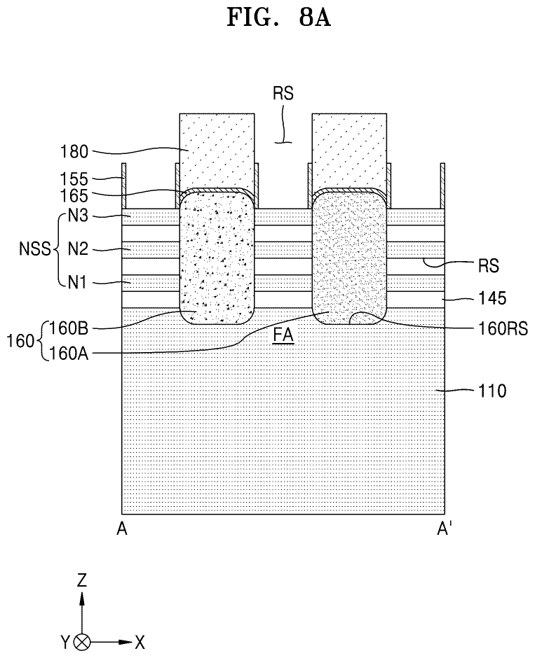

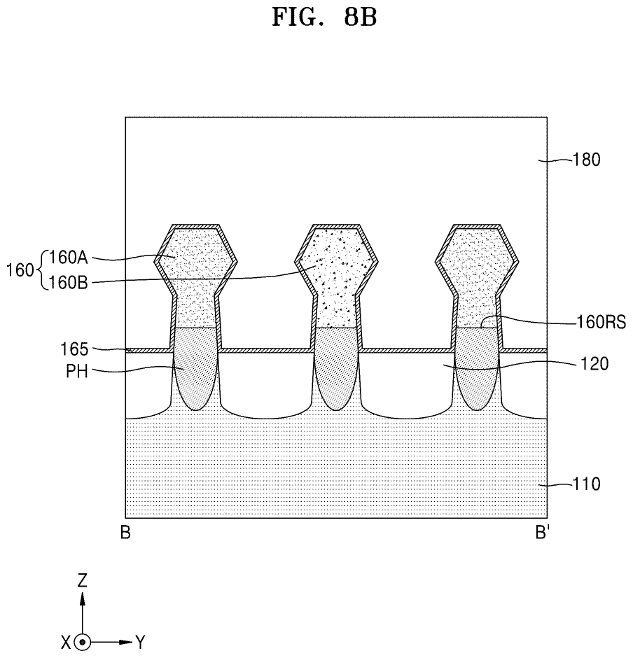

Referring to FIGS. 7A, 7B, and 8A to 8B together, the plurality of dummy gate electrodes D150 and the plurality of dummy insulating layers D145 are removed, and the plurality of sacrificial semiconductor layers 106S remaining on the fin-type active region FA are removed to form a plurality of removal spaces RS. When the plurality of dummy gate electrodes D150 and the plurality of dummy insulating layers D145 are removed, the plurality of sacrificial semiconductor layers 106S among the plurality of nanosheets N1, N2, and N3 are exposed on the fin-type active region FA, and the plurality of sacrificial semiconductor layers 106S may be removed through the spaces from which the plurality of dummy gate electrodes D150 and the plurality of dummy insulating layers D145 are removed. The plurality of removal spaces RS may be spaces that are formed when the plurality of dummy gate electrodes D150, the plurality of dummy insulating layers D145, and the plurality of sacrificial semiconductor layers 106S are removed.

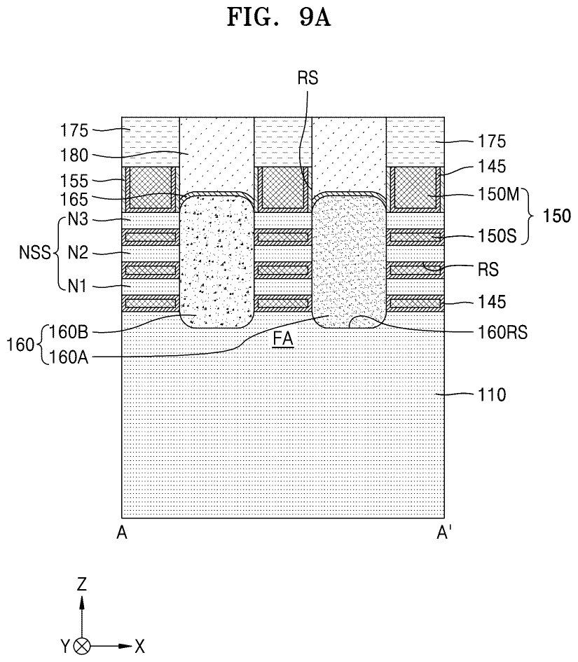

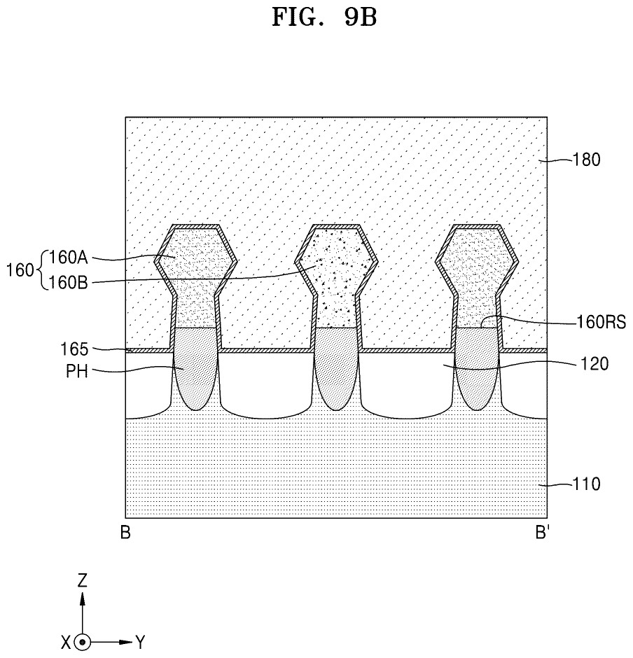

Referring to FIGS. 9A and 9B together, the plurality of gate insulating layers 145 are formed on surfaces exposed to the plurality of removal spaces RS, and the plurality of gate electrodes 150 are formed on the plurality of gate insulating layers 145 to fill at least parts of the plurality of removal spaces RS. The plurality of gate electrodes 150 may extend parallel to one another in the second horizontal direction (the Y direction).

The gate insulating layer 145 may include, for example, silicon oxide, a high dielectric material, or a combination thereof. For example, the gate insulating layer 145 may have a stacked structure of an interface layer and a high dielectric layer. In embodiments of the present inventive concept, the interface layer may include a low dielectric layer with a dielectric constant of about 9 or less, for example, silicon oxide, silicon oxynitride, or a combination thereof. In embodiments of the present inventive concept, the interface layer may be omitted. The high dielectric layer may include a material with a dielectric constant greater than that of silicon oxide. The high dielectric layer may include metal oxide or metal oxynitride. The high dielectric layer may include a material with a dielectric constant greater than that of a silicon oxide layer. For example, the high dielectric layer may have a dielectric constant of about 10 to about 25.

The high dielectric layer may include, for example, hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof. However, the present inventive concept is not limited thereto. The high dielectric layer may be formed by an atomic layer deposition (ALD) process, a chemical vapor deposition (CVD) process, or a physical vapor deposition (PVD) process. The high dielectric layer may have a thickness of about 10 Å to about 40 Å. However, the present inventive concept is not limited thereto.

The gate electrode 150 may include a metal-containing layer for controlling a work function and a metal-containing layer for gap-filling that fills a removal space on the metal-containing layer for controlling the work function. The metal-containing layer for controlling the work function may include at least one of, for example, titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and/or palladium (Pd). In embodiments of the present inventive concept, the gate electrode 150 may have a structure in which a metal nitride layer, a metal layer, a conductive capping layer, and a gap-fill metal layer are sequentially stacked. The metal nitride layer and the metal layer may include at least one of, for example, Ti, tantalum (Ta), W, Ru, Nb, Mo, and Hf. The gap-fill metal layer may include, for example, a W layer or an aluminum (Al) layer. In embodiments of the present inventive concept, the gate electrode 150 may include a stacked structure of TiAlC/TiN/W, a stacked structure of TiN/TaN/TiAlC/TiN/W, or a stacked structure of TiN/TaN/TiN/TiAlC/TiN/W. However, the present inventive concept is not limited thereto.

The gate electrode 150 includes a plurality of sub-gate portions 150S and a main gate portion 150M. Each of the plurality of sub-gate portions 150S is formed in a space between each of the plurality of nanosheets N1, N2, and N3 and between the fin-type active region FA and a first nanosheet N1 of the plurality of nanosheets N1, N2, and N3. The main gate portion 150M is connected to the plurality of sub-gate portions 150S and covers the nanosheet stacked structure NSS including the plurality of nanosheets N1, N2, and N3. In embodiments of the present inventive concept, a plurality of insulating spacers may be arranged on both ends of each of the plurality of sub-gate portions 150S with the gate insulating layer 145 therebetween.

A plurality of gate capping layers 175 may be formed on the plurality of gate electrodes 150 and the gate insulating layer 145. The plurality of gate capping layers 175 may respectively cover the plurality of gate electrodes 150. The gate capping layer 175 may include, for example, nitride. In embodiments of the present inventive concept, top surfaces of the plurality of gate capping layers 175 and a top surface of the inter-gate insulating layer 180 may be at substantially the same vertical level to be substantially coplanar with each other. For example, the plurality of gate insulating layers 145, the plurality of gate electrodes 150, and the plurality of gate capping layers 175 may fill all of the plurality of removal spaces RS. For example, after forming the plurality of gate insulating layers 145 on the surfaces exposed to the plurality of removal spaces RS, forming the plurality of gate electrodes 150 filling the plurality of removal spaces RS and covering the plurality of gate insulating layers 145, and removing parts of the plurality of gate insulating layers 145 and parts of the plurality of gate electrodes 150 filling upper portions of the plurality of removal spaces RS, the plurality of gate capping layers 175 may be formed to fill the upper portions of the plurality of removal spaces RS. The plurality of gate electrodes 150, the plurality of gate capping layers 175, the plurality of gate insulating layers 145, and the plurality of gate spacers 155 may respectively form a plurality of gate structures.

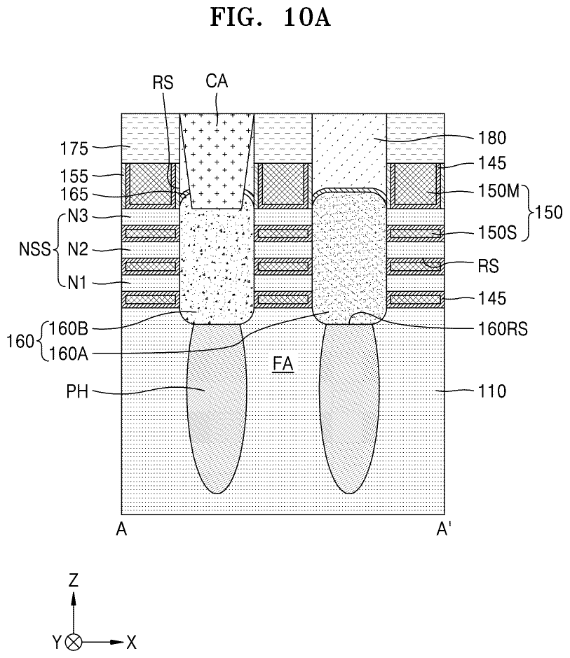

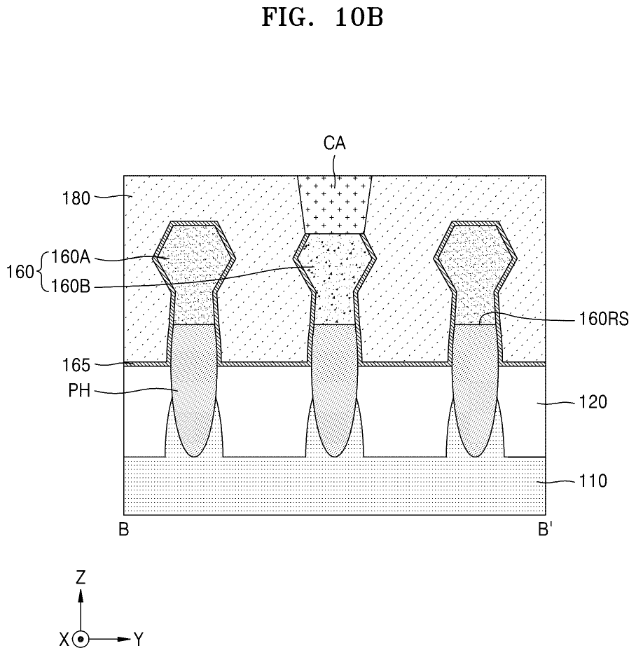

Referring to FIGS. 10A and 10B together, the contact plug CA is formed to pass through the inter-gate insulating layer 180 and the etch stop layer 165 and to contact and be electrically connected to a corresponding source/drain region 160. In addition, a gate contact plug may be formed to pass through the gate capping layer 175 and to contact and be electrically connected to the gate electrode 150.

In embodiments of the present inventive concept, the contact plug CA and the gate contact plug may include a conductive barrier layer and a conductive core layer covering the conductive barrier layer. The conductive barrier layer may include, for example, Ti, Ta, TiN, TaN, or a combination thereof, and the conductive core layer may include, for example, Co, W, copper (Cu), Ru, iridium (Ir), Mo, or a combination thereof.

In embodiments of the present inventive concept, the contact plug CA may be connected to the drain region 160B among the plurality of source/drain regions 160, but might not be connected to the source region 160A. For example, the contact plug CA may pass through the inter-gate insulating layer 180 and may contact and be electrically connected to the drain region 160B among the plurality of source/drain regions 160.

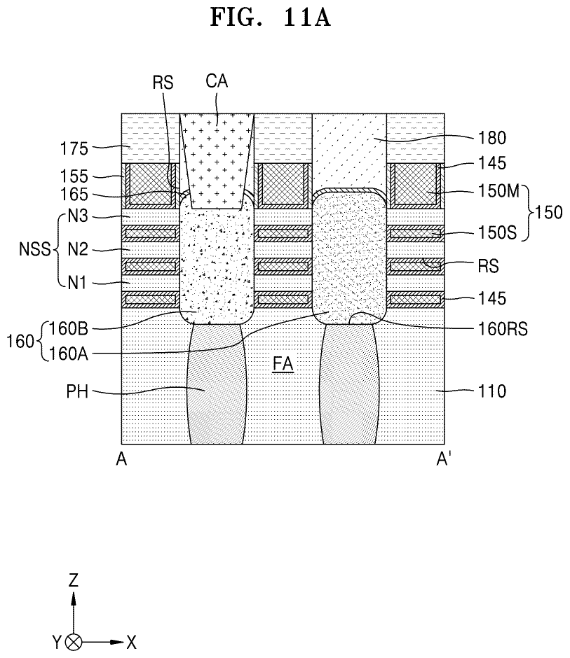

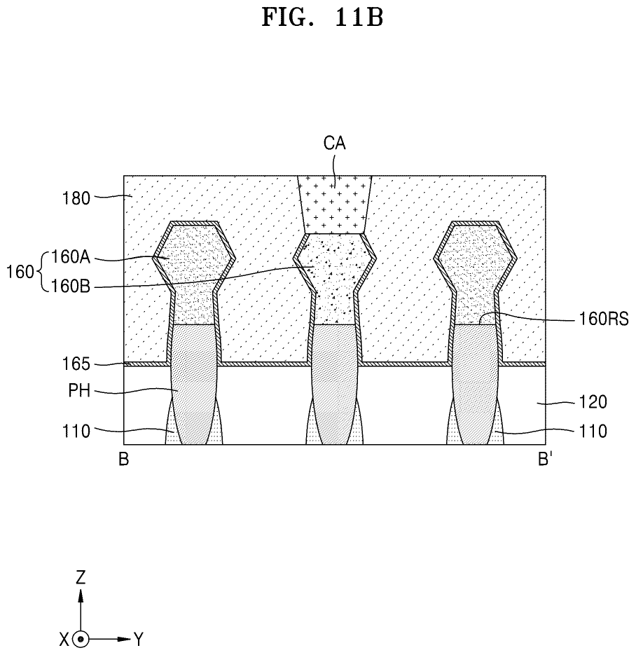

Referring to FIGS. 11A and 11B together, a lower portion of the substrate 110 is partially removed to expose the placeholder structure PH and the device isolation layer 120. The lower portion of the substrate 110 may be partially removed by performing a back-lap process or a back grinding process. A part of the substrate 110 may be interposed between the device isolation layer 120 and the placeholder structure PH in the second horizontal direction (the Y direction). In the process of partially removing the lower portion of the substrate 110, a lower portion of the placeholder structure PH may be partially removed too. For example, after partially removing the lower portion of the substrate 110, the placeholder structure PH may have a height of about 25 nm to about 60 nm.

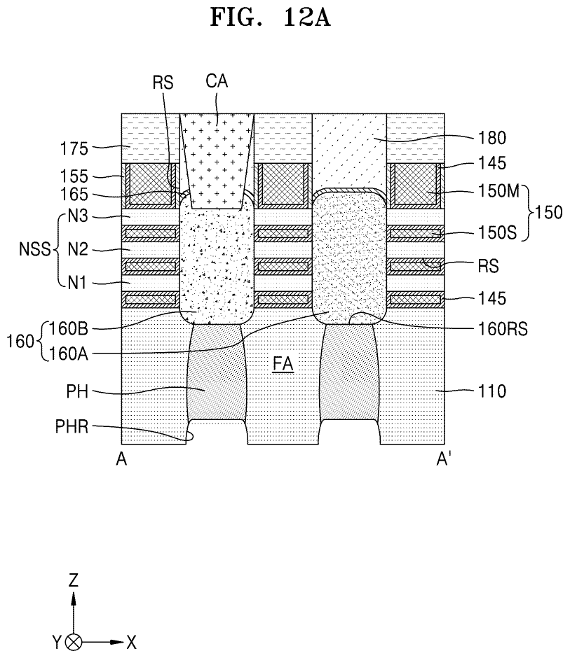

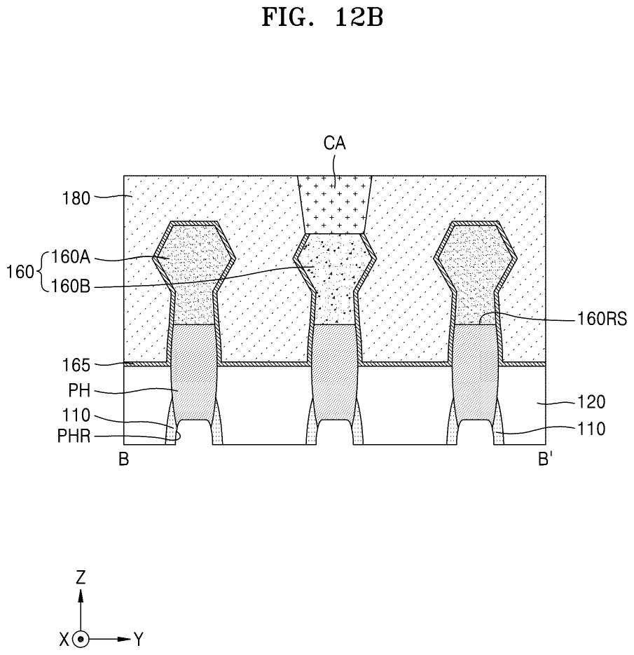

Referring to FIGS. 12A and 12B together, a lower portion of the exposed placeholder structure PH is partially removed to form a placeholder recess PHR. The placeholder recess PHR may extend upward from the bottom surface of the substrate 110 toward an upper portion of the placeholder recess PHR. The substrate 110 may surround the placeholder recess PHR. The placeholder recess PHR may be limited by the substrate 110 and the placeholder structure PH.

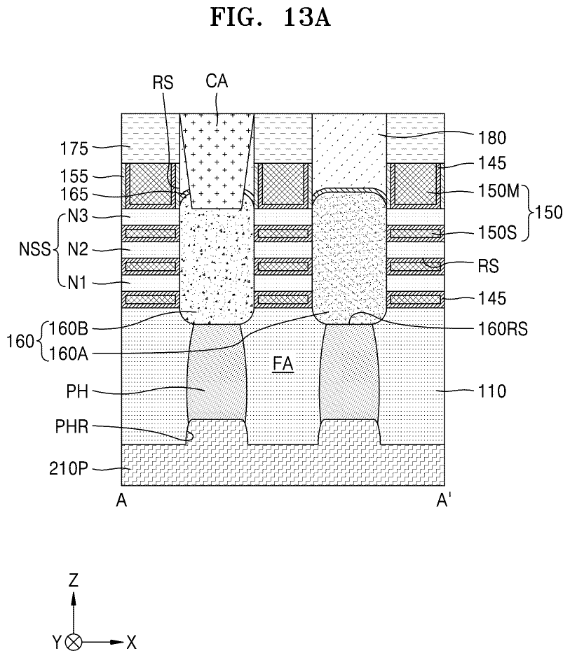

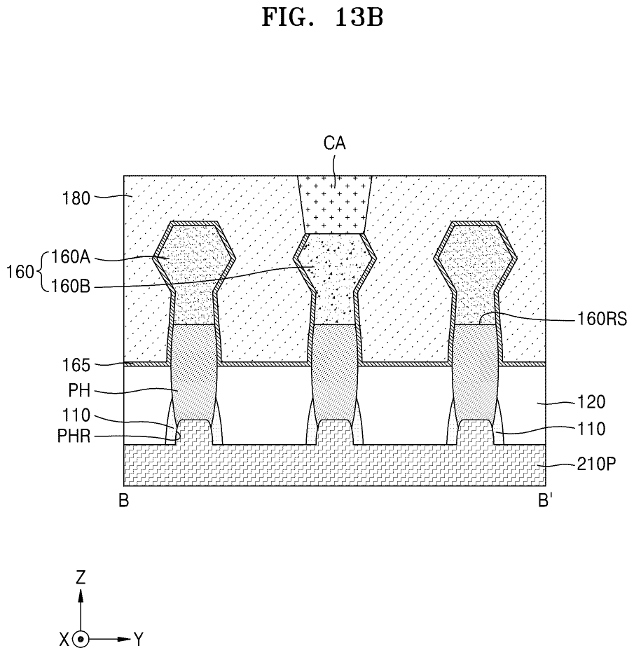

Referring to FIGS. 13A and 13B together, a hard mask material layer 210P is formed to fill the placeholder recess PHR and to cover the bottom surface of the substrate 110 and a bottom surface of the device isolation layer 120. The hard mask material layer 210P may include a material having etch selectivity with respect to the substrate 110 and the device isolation layer 120. In embodiments of the present inventive concept, the hard mask material layer 210P may include a material having etch selectivity with respect to each of the substrate 110, the device isolation layer 120, and the placeholder structure PH. For example, the hard mask material layer 210P may include TiN, AlO, or AlN. However, the present inventive concept is not limited thereto. In embodiments of the present inventive concept, the hard mask material layer 210P may include a material that may be removed by a wet etching process.

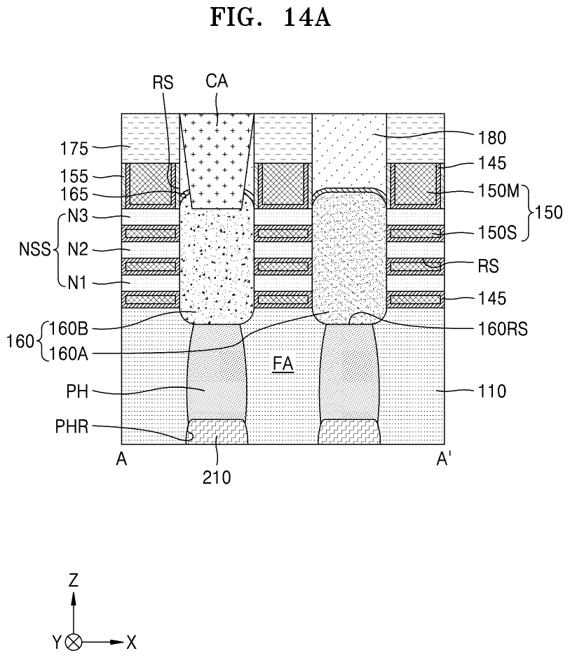

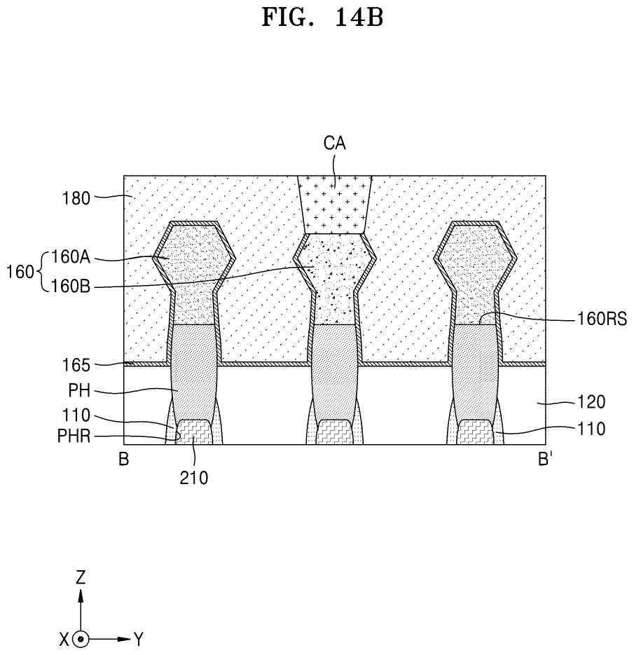

Referring to FIGS. 13A, 13B, 14A, and 14B together, a part of the hard mask material layer 210P is removed to form a hard mask layer 210 filling the placeholder recess PHR. The hard mask layer 210 may be formed by partially removing a lower portion of the hard mask material layer 210P until the substrate 110 and the device isolation layer 120 are exposed. In embodiments of the present inventive concept, the hard mask layer 210 may be formed by partially removing the lower portion of the hard mask material layer 210P by performing a wet etching process. The hard mask layer 210 may be formed to have a thickness of about 5 nm to about 8 nm.

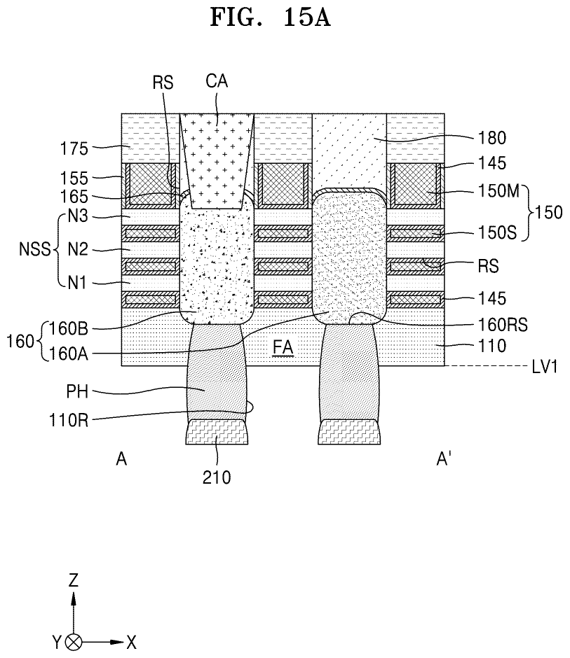

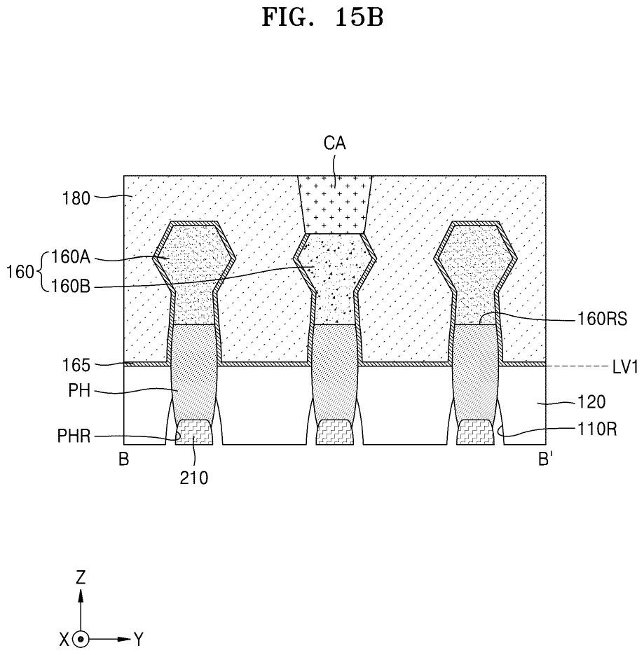

Referring to FIGS. 15A and 15B together, the lower portion of the substrate 110 is partially removed to form a substrate recess 110R. A side surface of the hard mask layer 210 and a part of a side surface of the placeholder structure PH may be exposed in the substrate recess 110R. The substrate recess 110R may be formed by partially removing the lower portion the substrate 110 by performing an etching process having etch selectivity on the hard mask layer 210, the placeholder structure PH, and the device isolation layer 120. In embodiments of the present inventive concept, the substrate recess 110R may be formed by partially removing the lower portion the substrate 110 by performing a dry etching process and a wet etching process together. The substrate recess 110R may be limited by the bottom surface of the substrate 110, the side surface of the hard mask layer 210, and the side surface of the placeholder structure PH.

In embodiments of the present inventive concept, after partially removing the lower portion of the substrate 110 to form the substrate recess 110R, the bottom surface of the substrate 110 may be at a first vertical level LV1. The first vertical level LV1 may be the lowermost vertical level of the etch stop layer 165. The first vertical level LV1 may be lower than the lowermost end of the source/drain region 160. The first vertical level LV1 may be lower than the top surface of the substrate 110.

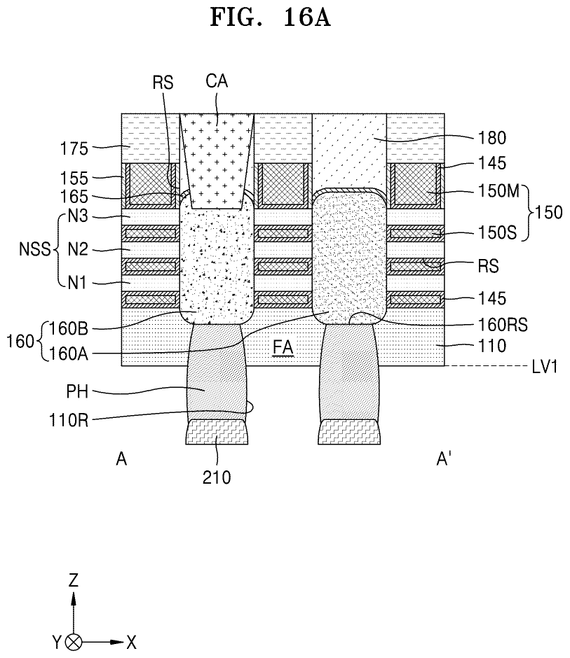

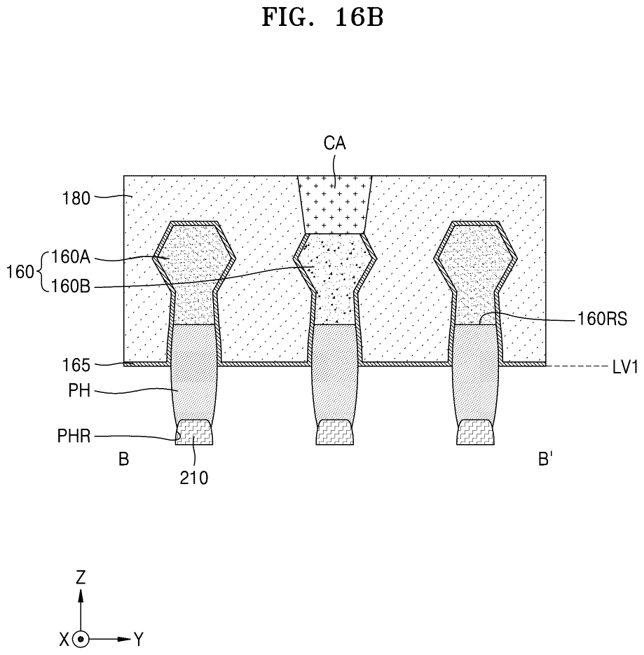

Referring to FIGS. 15A, 15B, 16A, and 16B together, the device isolation layer 120 is removed to further expose the side surface of the hard mask layer 210 and a part of the side surface of the placeholder structure PH. After the device isolation layer 120 is removed, the etch stop layer 165 may be exposed. For example, both the side surface of the hard mask layer 210 and a part of the side surface of the placeholder structure PH, which is lower than the first vertical level LV1, may be exposed.

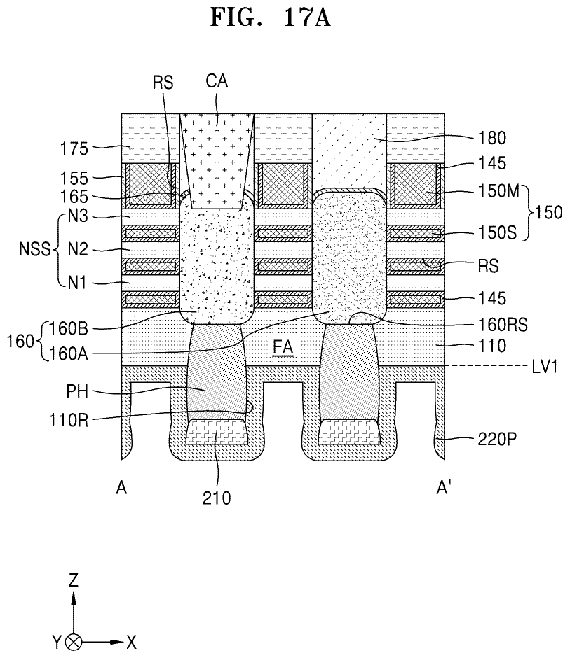

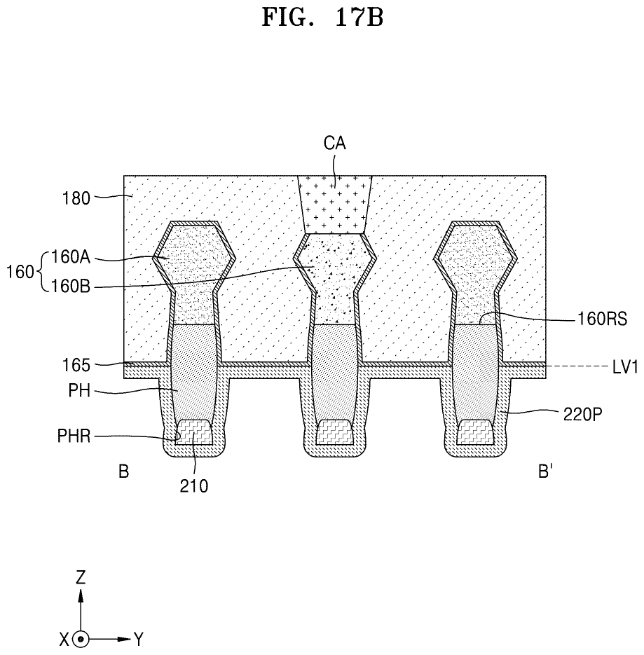

Referring to FIGS. 17A and 17B together, a spacer material layer 220P is formed to cover the bottom surface of the substrate 110, a bottom surface of the etch stop layer 165, the side surface and a bottom surface of the hard mask layer 210, and the side surface of the placeholder structure PH. The spacer material layer 220P may be formed to conformally cover the bottom surface of the substrate 110, the bottom surface of the etch stop layer 165, the side surface and the bottom surface of the hard mask layer 210, and the side surface of the placeholder structure PH. For example, the spacer material layer 220P may be formed not to completely fill the substrate recess 110R. The spacer material layer 220P may include a material having etch selectivity with respect to the substrate 110 and the placeholder structure PH. For example, the spacer material layer 220P may include silicon oxide, silicon oxynitride, silicon oxycarbide, or silicon carbonitride. However, the present inventive concept is not limited thereto. The spacer material layer 220P may be formed to have a thickness of about 5 nm to about 10 nm.

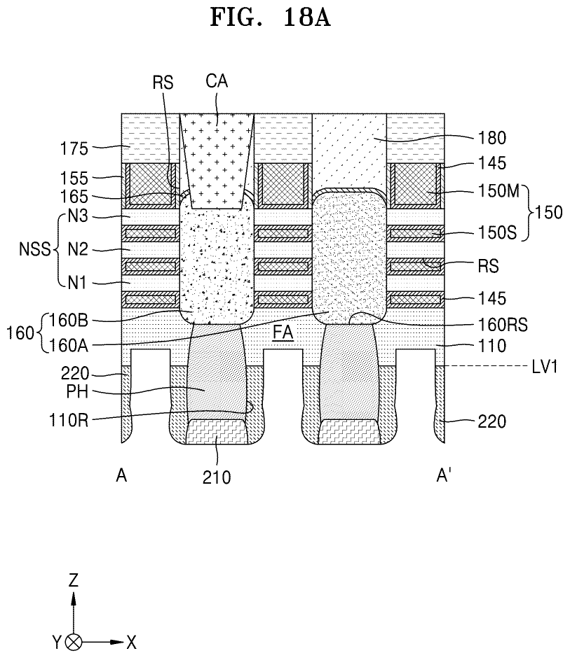

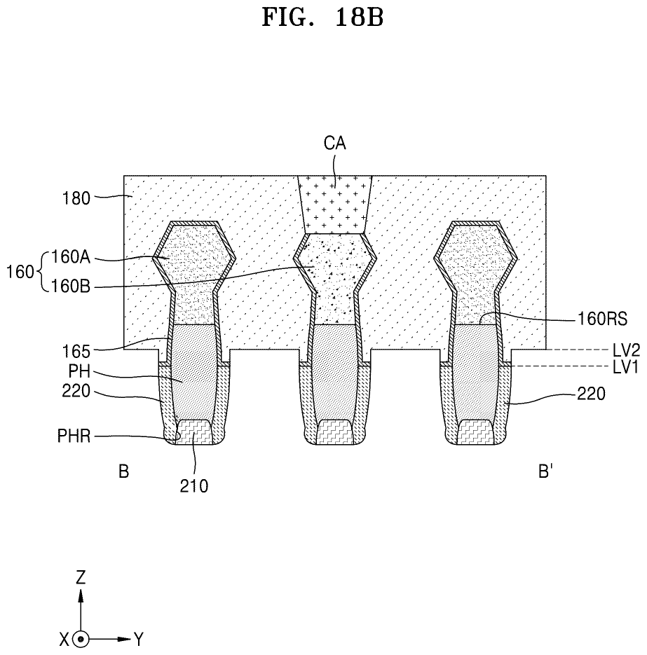

Referring to FIGS. 17A, 17B, 18A, and 18B together, anisotropic etching is performed to remove a part of the spacer material layer 220P to form a spacer layer 220. The spacer layer 220 may cover the side surface of the hard mask layer 210 and a lower portion of the side surface of the placeholder structure PH. For example, the spacer layer 220 might expose the hard mask layer 210. In embodiments of the present inventive concept, in the process of removing a part of the spacer material layer 220P to form the spacer layer 220, the lower portion of the substrate 110 and a lower portion of the inter-gate insulating layer 180 may be partially removed. For example, the lower portion of the inter-gate insulating layer 180 may be partially removed so that a part of the bottom surface of the inter-gate insulating layer 180 may be at a second vertical level LV2 that is higher than the remaining part of the bottom surface of the inter-gate insulating layer 180. The second vertical level LV2 is higher than the first vertical level LV1.

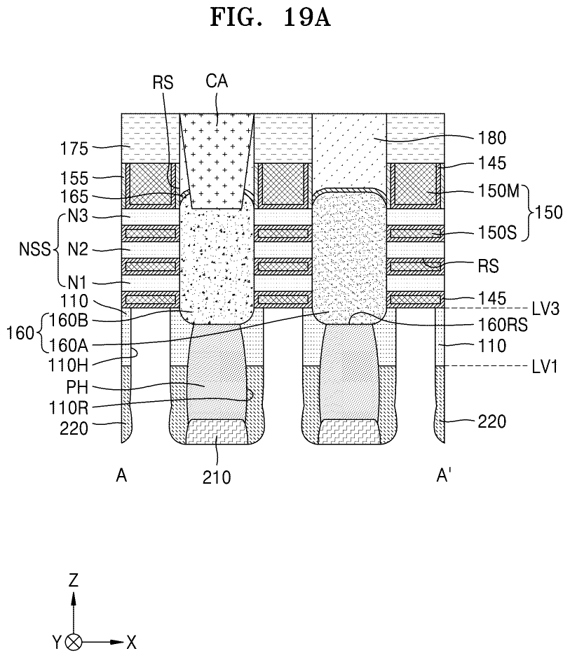

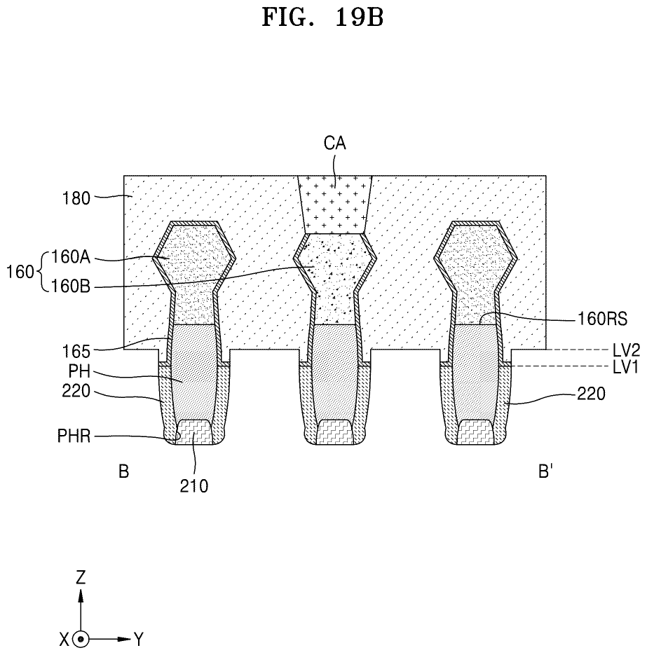

Referring to FIG. 19A and FIG. 19B together, a portion of the substrate 110 exposed between the spacer layers 220 is removed to form a substrate hole 110H exposing the gate insulating layer 145 surrounding the lowermost sub-gate portion 150S among the plurality of sub-gate portions 150S.

In embodiments of the present inventive concept, the substrate hole 110H may be formed by removing a part of the substrate 110 by performing a dry etching process until the gate insulating layer 145 surrounding the lowermost sub-gate portion 150S among the plurality of sub-gate portions 150S is exposed, and then performing a wet etching process to expose the gate insulating layer 145 and to remove another part of the substrate 110. The uppermost end of the substrate hole 110H, that is, the lowermost end of the gate insulating layer 145 surrounding the lowermost sub-gate portion 150S among the plurality of sub-gate portions 150S may be at a third vertical level LV3 higher than the second vertical level LV2.

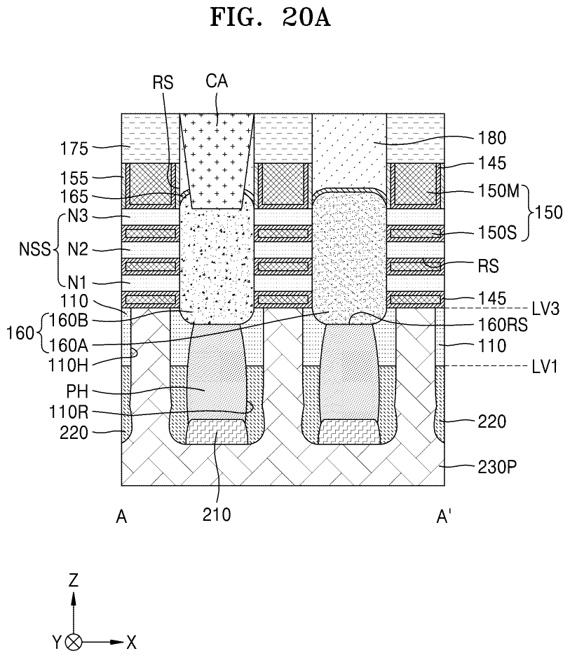

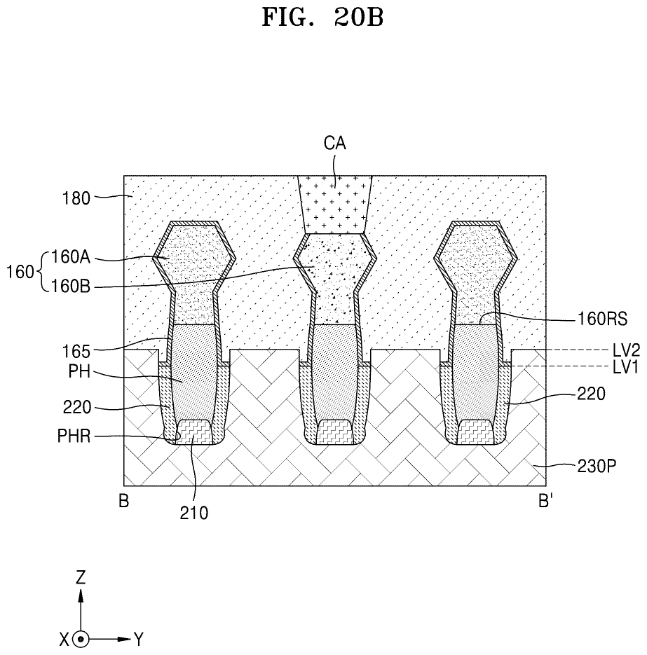

Referring to FIGS. 20A and 20B together, a cover insulating material layer 230P is formed to fill the substrate hole 110H and to cover the inter-gate insulating layer 180, the spacer layer 220, and the hard mask layer 210. The cover insulating material layer 230P may include nitride. In embodiments of the present inventive concept, the cover insulating material layer 230P may include silicon nitride. The cover insulating material layer 230P may be formed to have a predetermined thickness to cover the spacer layer 220 and the hard mask layer 210. For example, a bottom surface of the cover insulating material layer 230P may be at a vertical level lower than the lowermost end of the spacer layer 220 and the lowermost end of the hard mask layer 210.

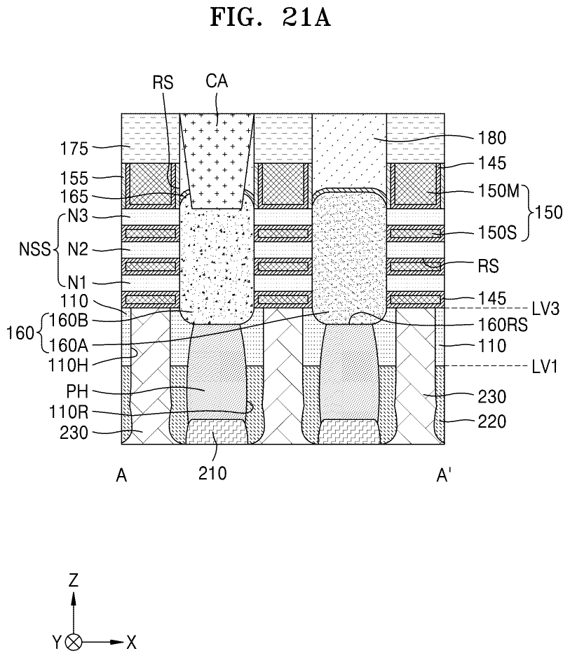

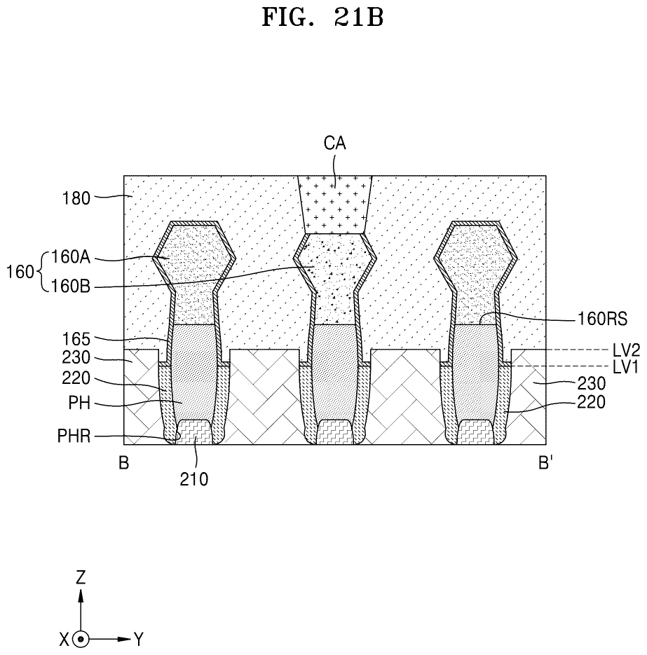

Referring to FIGS. 20A, 20B, 21A, and 21B together, a lower portion of the cover insulating material layer 230P is partially removed to form a cover insulating layer 230. The cover insulating layer 230 may be formed by partially removing the lower portion of the cover insulating material layer 230P until the hard mask layer 210 is exposed. For example, the cover insulating layer 230 may be formed by partially removing the lower portion of the cover insulating material layer 230P by performing a chemical mechanical polishing (CMP) process.

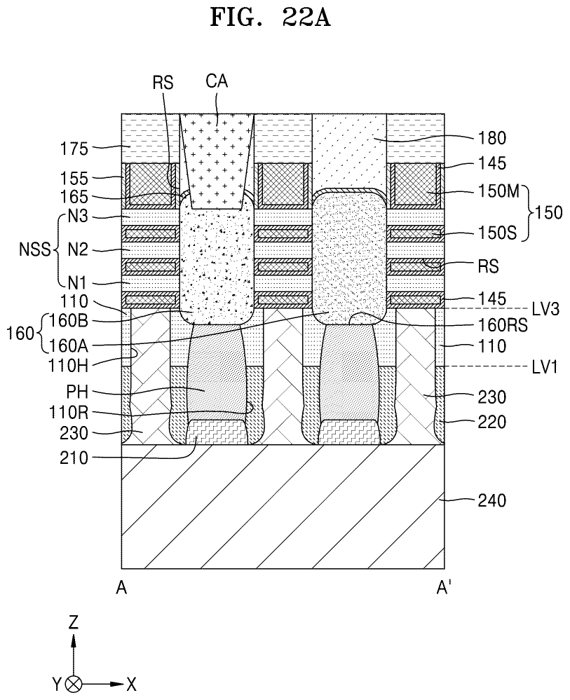

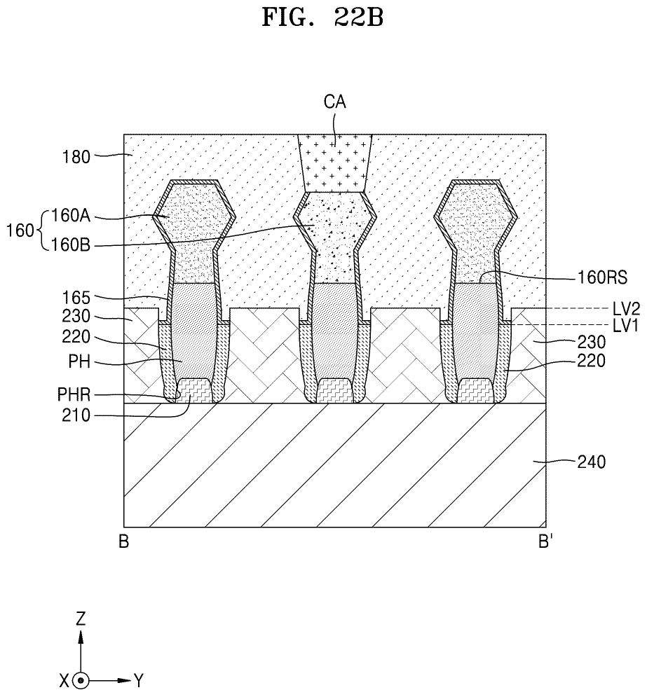

Referring to FIGS. 22A and 22B together, a rear insulating layer 240 is formed to cover bottoms of the cover insulating layer 230 and the hard mask layer 210. The rear insulating layer 240 may include an oxide. For example, the rear insulating layer 240 may include silicon oxide. In embodiments of the present inventive concept, the rear insulating layer 240 may include high density plasma (HDP) oxide or tetraethylorthosilicate (TEOS) oxide.

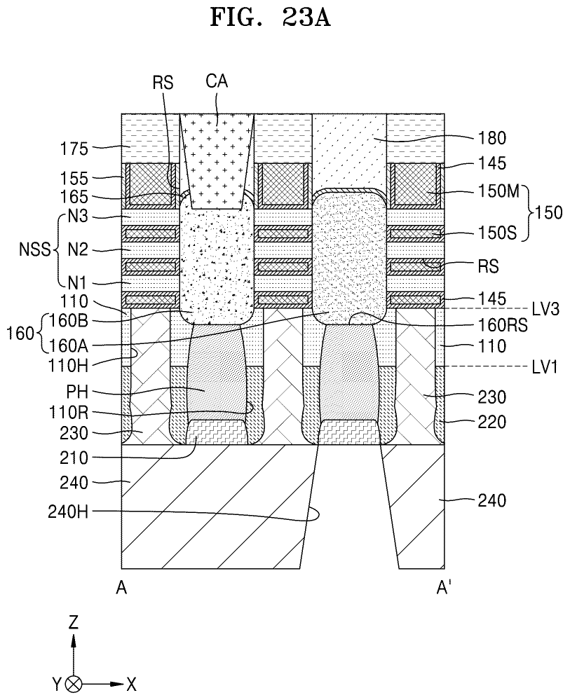

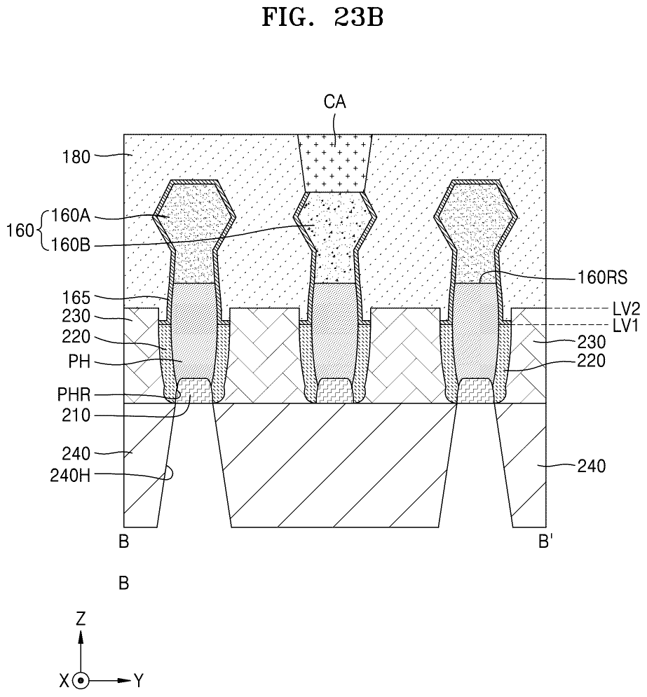

Referring to FIGS. 23A and 23B together, a part of the rear insulating layer 240 is removed to form a rear through hole 240H passing through the rear insulating layer 240. The hard mask layer 210 may be exposed in the rear through hole 240H. For example, a bottom surface of the hard mask layer 210 may be the top surface of the rear through hole 240H. The rear through hole 240H might not overlap the source/drain region 160 that is connected to the contact plug CA in the vertical direction (the Z direction), but may overlap the source/drain region 160 that is not connected to the contact plug CA. In embodiments of the present inventive concept, the hard mask layer 210 exposed in the rear through hole 240H may cover the bottom surface of the placeholder structure PH that is under the source region 160A. For example, the rear through hole 240H may overlap the source region 160A in the vertical direction (the Z direction), but might not overlap the drain region 160B.

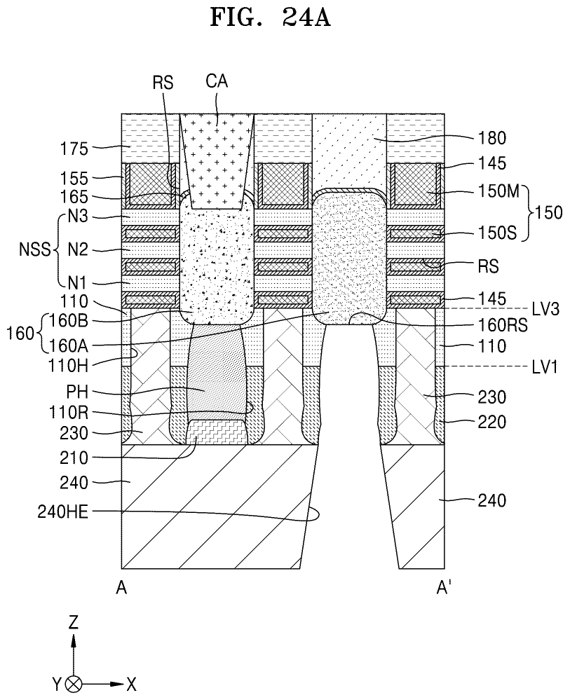

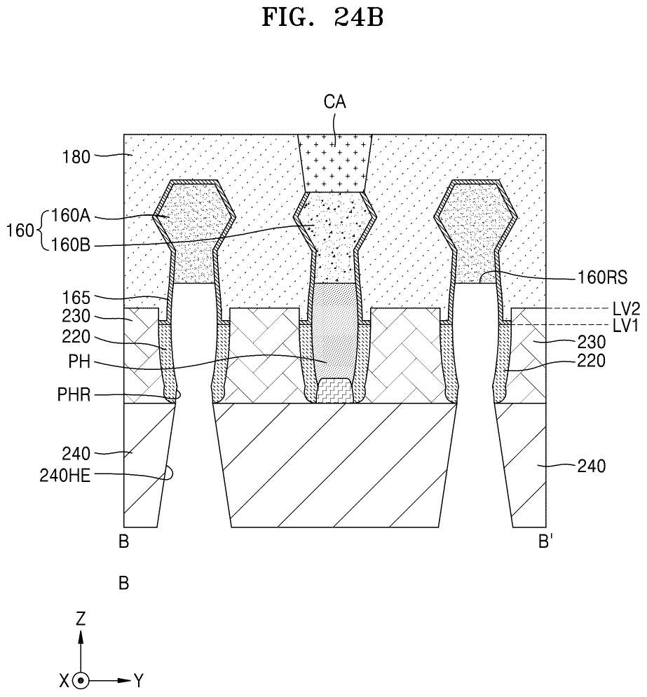

Referring to FIGS. 23A, 23B, 24A, and 24B together, the hard mask layer 210 and the placeholder structure PH are removed through the rear through hole 240H to expose the source/drain region 160. The rear through hole 240H may be an extended through hole 240HE with a space from which the hard mask layer 210 and the placeholder structure PH are removed. The source/drain region 160 may be exposed through the extended through hole 240HE.

The extended through hole 240HE might not overlap the source/drain region 160 that are connected to the contact plug CA in the vertical direction (the Z direction), but may overlap the source/drain region 160 that is not connected to the contact plug CA. In embodiments of the present inventive concept, the source region 160A may be exposed in the extended through hole 240HE. For example, the extended through hole 240HE may overlap the source region 160A in the vertical direction (the Z direction), but might not overlap the drain region 160B.

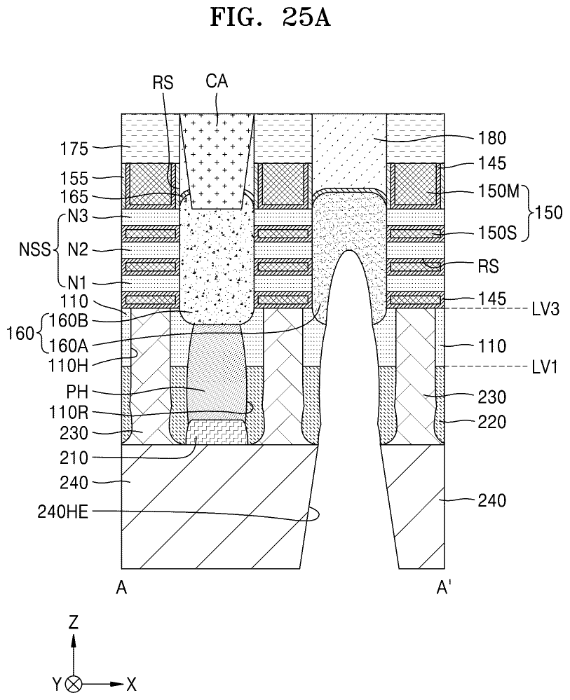

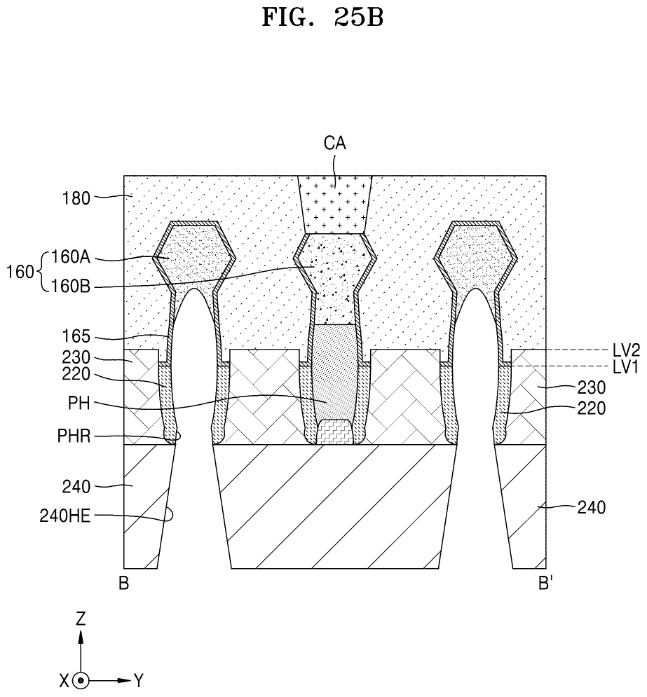

Referring to FIGS. 25A and 25B together, a part of the source/drain region 160 that is exposed through the extended through hole 240HE is removed. For example, a part of the source region 160A that is exposed through the extended through hole 240HE may be removed.

FIGS. 26A and 26B are cross-sectional views illustrating an integrated circuit device 1 according to embodiments of the present inventive concept. Specifically, FIG. 26A is a cross-sectional view taken along the line A-A′ of FIG. 1, and FIG. 26B is a cross-sectional view taken along the line B-B′ of FIG. 1.

Referring to FIGS. 26A and 26B together, the integrated circuit device 1 is formed by forming a rear contact plug 250 filling the extended through hole 240HE. The rear contact plug 250 may include a rear conductive barrier layer covering a surface of the source/drain region 160 that is exposed in the extended through hole 240HE, a surface of the substrate 110, a surface of the spacer layer 220, and a surface of the rear insulating layer 240. The rear contact plug 250 may additionally include a rear conductive core layer covering the rear conductive barrier layer and filling the extended through hole 240HE. In embodiments of the present inventive concept, the rear conductive barrier layer may conformally cover the surface of the source/drain region 160 exposed in the extended through hole 240HE, the surface of the substrate 110, the surface of the spacer layer 220, and the surface of the rear insulating layer 240. The rear conductive barrier layer may include, for example, Ti, Ta, TiN, TaN, or a combination thereof, and the rear conductive core layer may include, for example, Co, W, Cu, Ru, Ir, Mo, or a combination thereof. The rear contact plug 250 may be the rear contact plug BCA illustrated in FIG. 1.

The integrated circuit device 1 may be a logic semiconductor chip. For example, the integrated circuit device 1 may be a central processing unit (CPU) chip, a graphics processing unit (GPU) chip, or an application processor (AP) chip.

In the current specification, the logic semiconductor chip refers to a semiconductor chip that is not a memory semiconductor chip and performs logical operations. For example, the logic semiconductor chip may include a logic cell. In embodiments of the present inventive concept, the logic semiconductor chip may include both the logic cell and a memory cell.

Referring to FIGS. 1, 26A, and 26B together, the integrated circuit device 1 includes the rear insulating layer 240, the cover insulating layer 230 and the substrate 110, which are on the rear insulating layer 240, the plurality of nanosheet stacked structures NSS, which are on the cover insulating layer 230 and the substrate 110, and the plurality of gate electrodes 150, which extend parallel to one another in the second horizontal direction (the Y direction) intersecting the first horizontal direction (the X direction) on the substrate 110, the cover insulating layer 230, and the plurality of nanosheet stacked structures NSS. The gate electrode 150 may be the gate electrode GL illustrated in FIG. 1.

The substrate 110 may have the plurality of substrate holes 110H passing through the substrate 110, and the cover insulating layer 230 may fill the plurality of substrate holes 110H. In embodiments of the present inventive concept, the integrated circuit device 1 may include a multi-gate metal oxide semiconductor field effect transistor (MOSFET) composed of the nanosheet stacked structure NSS. The nanosheet stacked structure NSS may be referred to as a channel region. In embodiments of the present inventive concept, the multi-gate MOSFET included in the integrated circuit device I may be composed of an upper portion of the substrate 110 and the nanosheet stacked structure NSS. For example, the upper portion of the substrate 110 and the nanosheet stacked structure NSS may constitute the channel region. The channel region may extend in the first horizontal direction (the X direction). The plurality of gate insulating layers 145 may be interposed between the channel region and the plurality of gate electrodes 150.

In the current specification, the integrated circuit device 1 is described as including the multi-gate MOSFET. However, the present inventive concept is not limited thereto. For example, it may be apparent to those skilled in the art that the integrated circuit device 1 may include a single gate MOSFET composed of the fin-type active region FA (refer to FIGS. 2A and 2B) instead of the multi-gate MOSFET composed of the nanosheet stacked structure NSS. When the integrated circuit device 1 includes the single gate MOSFET composed of the fin-type active region FA instead of the multi-gate MOSFET composed of the nanosheet stacked structure NSS, the fin-type active region FA may be referred to as the channel region.

Each of the plurality of nanosheet stacked structures NSS may include the plurality of nanosheets N1, N2, and N3 arranged to be spaced apart from the top surface of the substrate 110 in the vertical direction (the Z direction). The plurality of nanosheets N1, N2, and N3 may extend parallel to the top surface of the substrate 110. Each of the plurality of nanosheets N1, N2, and N3 may have a length of about 5 nm to about 30 nm in the first horizontal direction (the X direction).

The plurality of nanosheets N1, N2, and N3 constituting one nanosheet stacked structure NSS are sequentially stacked on the top surface of the substrate 110. In the current example, a case in which one nanosheet stacked structure NSS includes three nanosheets N1, N2, and N3 is illustrated. However, the present inventive concept is not limited thereto. For example, the plurality of nanosheets N1, N2, and N3 may include a single material. In embodiments of the present inventive concept, the plurality of nanosheets N1, N2, and N3 may include the same material as that of the substrate 110.

On the substrate 110 and the plurality of nanosheet stacked structures NSS, the plurality of gate electrodes 150 may extend parallel to one another in the second horizontal direction (the Y direction) intersecting the first horizontal direction (the X direction). At least a part of each of the plurality of gate electrodes 150 may overlap each of the plurality of nanosheet stacked structures NSS in the vertical direction (the Z direction).

Each of the plurality of gate electrodes 150 may cover the nanosheet stacked structure NSS and surround at least parts of the plurality of nanosheets N1, N2, and N3. The gate electrode 150 may include the main gate portion 150M and the plurality of sub-gate portions 150S. The main gate portion 150M may cover side surfaces of the nanosheet stacked structure NSS, and the plurality of sub-gate portions 150S may be connected to the main gate portion 150M and formed in spaces between the substrate 110 and the first nanosheet N1 and between the plurality of nanosheets N1, N2, and N3. The gate insulating layer 145 is formed on the gate electrode 150. The gate insulating layer 145 may be formed between the nanosheet stacked structure NSS and the gate electrode 150. For example, the gate insulating layer 145 may be disposed between the main gate portion 150M and a third nano sheet N3 of the plurality of nanosheets N1, N2, and N3, between the plurality of nanosheets N1, N2, and N3 and the plurality of sub-gate portions 150S, between the substrate 110 and the lowermost sub-gate portion 150S of the plurality of sub-gate portions 150S, and between the source/drain region 160 and the gate electrode 150. The plurality of gate capping layers 175 may be respectively arranged on the plurality of gate electrodes 150. The plurality of gate capping layers 175 may respectively cover the plurality of gate electrodes 150.

The plurality of gate spacers 155 may respectively cover side surfaces of the plurality of gate electrodes 150. In embodiments of the present inventive concept, the plurality of gate spacers 155 may cover the side surfaces of the plurality of gate electrodes 150 with the plurality of gate insulating layers 145 therebetween. In embodiments of the present inventive concept, the plurality of gate spacers 155 may respectively cover the side surfaces of the plurality of gate electrodes 150 and side surfaces of the plurality of gate capping layers 175. The uppermost end of the gate electrode 150 and the uppermost end of the gate insulating layer 145 are illustrated as being at substantially the same vertical level. However, the present inventive concept is not limited thereto. In embodiments of the present inventive concept, the uppermost end of the gate insulating layer 145 may be at a vertical level higher than the uppermost end of the gate electrode 150, but may be at substantially the same vertical level as or a lower vertical level than that of the uppermost end of the gate capping layer 175.

In embodiments of the present inventive concept, the gate spacer 155 may cover both side surfaces of the gate electrode 150 in the first horizontal direction (the X direction) and both side surfaces of the gate electrode 150 in the second horizontal direction (the Y direction), and may completely surround the gate electrode 150 in a top-view. The plurality of gate electrodes 150, the plurality of gate capping layers 175, the plurality of gate insulating layers 145, and the plurality of gate spacers 155 may respectively form the plurality of gate structures.

The gate electrode 150 may be formed by using a replacement metal gate (RMG) process. For example, after forming the dummy insulating layer D145 (refer to FIG. 3A) and the dummy gate electrode D150 (refer to FIG. 3A) on the fin-type active region FA, the gate spacer 155 surrounding the dummy insulating layer D145 and the dummy gate electrode D150 may be formed, and after removing the dummy insulating layer D145 and the dummy gate electrode D150, the gate insulating layer 145 and the gate electrode 150 may be formed in a space surrounded by the gate spacer 155.

The plurality of source/drain regions 160 are formed on the substrate 110. Each of the plurality of source/drain regions 160 is connected to one end of each of the plurality of neighboring nanosheets N1, N2, and N3. Each of the plurality of source/drain regions 160 may be formed on a part of the substrate 110 between a pair of gate electrodes 150 adjacent to each other in the first horizontal direction (the X direction). In embodiments of the present inventive concept, the plurality of source/drain regions 160 may extend inward from the top surface of the substrate 110. In embodiments of the present inventive concept, the plurality of source/drain regions 160 may extend inward from the top surface of the substrate 110, but might not extend to the bottom surface of the substrate 110. Each of the plurality of source/drain regions 160 may include the source region 160A and the drain region 160B. In embodiments of the present inventive concept, the source region 160A and the drain region 160B may be alternately arranged in the first horizontal direction (the X direction).

The etch stop layer 165 may conformally cover the surfaces of the plurality of source/drain regions 160, and the inter-gate insulating layer 180 may fill spaces among the plurality of gate structures. In embodiments of the present inventive concept, the inter-gate insulating layer 180 may cover the etch stop layer 165, may fill the spaces among the plurality of gate structures, and may surround the plurality of source/drain regions 160.

The contact plug CA may pass through the inter-gate insulating layer 180 and the etch stop layer 165 and be electrically connected to the source/drain region 160. In embodiments of the present inventive concept, the contact plug CA may be electrically connected to the drain region 160B, but might not be electrically connected to the source region 160A. In some embodiments, the contact plug CA may be formed to have a tapered shape in which a horizontal width of the contact plug CA decreases while extending from top to bottom in the vertical direction (the Z direction).

The plurality of spacer layers 220 may be arranged on the bottom surface of the substrate 110, and the substrate 110 may have the substrate hole 110H exposing the gate insulating layer 145 surrounding the lowermost sub-gate portion 150S among the plurality of sub-gate portions 150S through a portion of the substrate 110 exposed between a pair of adjacent spacer layers 220. The substrate hole 110H may have a horizontal width of about 7 nm to about 20 nm in the first horizontal direction (the X direction). The cover insulating layer 230 may fill the substrate hole 110H under the inter-gate insulating layer 180 and the etch stop layer 165. The rear insulating layer 240 may cover the bottoms of the cover insulating layer 230 and the hard mask layer 210.

The extended through hole 240HE may pass through the rear insulating layer 240, the cover insulating layer 230, and the substrate 110 and extend into at least some of the plurality of source/drain regions 160. The rear contact plug 250 may fill the extended through hole 240HE and may be connected to the source/drain region 160. The rear contact plug 250 may pass through the rear insulating layer 240 and the cover insulating layer 230 and be connected to the source/drain region 160. The spacer layer 220 or the spacer layer 220 and the substrate 110 may be interposed between the rear contact plug 250 and the cover insulating layer 230. For example, the rear contact plug 250 may extend from a bottom surface of the source/drain region 160 into the source/drain region 160 by about 10 nm to about 20 nm. The rear contact plug 250 may extend from a bottom surface of the rear insulating layer 240 to the source/drain region 160 through the rear surface of the substrate 110. The rear insulating layer 240, the spacer layer 220, and the substrate 110 may surround the rear contact plug 250 and/or the placeholder structure PH. The spacer layer 220 surrounding the rear contact plug 250 or the placeholder structure PH may be interposed between the rear insulating layer 240 and the substrate 110. A thickness of the spacer layer 220 covering the rear contact plug 250 or the placeholder structure PH may be about 5 nm to about 10 nm in the horizontal direction. In embodiments of the present inventive concept, the rear contact plug 250 may be connected to the source region 160A, but might not be connected to the drain region 160B among the plurality of source/drain regions 160. The placeholder structure PH may be connected to the drain region 160B, but might not be connected to the source region 160A among the plurality of source/drain regions 160. The spacer layer 220 surrounding the rear contact plug 250 may be referred to as a contact spacer layer, and the spacer layer 220 surrounding the placeholder structure PH may be referred to as a placeholder spacer layer. For example, the plurality of spacer layers 220 may include the contact spacer layer and the placeholder spacer layer.

In embodiments of the present inventive concept, the rear contact plug 250 may have a tapered shape in which a horizontal width of the rear contact plug 250 decreases while extending from bottom to top in the vertical direction (the Z direction). For example, the rear contact plug 250 may have a horizontal width of about 30 nm to about 60 nm at the lowermost end and may have a horizontal width of about 10 nm to about 15 nm at a portion contacting the source/drain region 160. At the portion at which the rear contact plug 250 contacts the source/drain region 160, the horizontal width of the rear contact plug 250 may be less than the horizontal width of the source/drain region 160. For example, the rear contact plug 250 may have a horizontal width of about 12 nm to about 18 nm at a portion contacting the lowermost end of the spacer layer 220. In embodiments of the present inventive concept, the rear contact plug 250 may have a dent portion concave inward at the portion contacting the spacer layer 220. The dent portion of the rear contact plug 250 may be at a vertical level higher than that of the lowermost end of the spacer layer 220 and lower than that of the uppermost end of the spacer layer 220.

The uppermost end of the spacer layer 220 may be at a vertical level lower than that of the uppermost end of the rear contact plug 250, and the lowermost end of the spacer layer 220 may be at a vertical level higher than that of the lowermost end of the rear contact plug 250. The uppermost end of the spacer layer 220 may contact the substrate 110 and the etch stop layer 165, and the lowermost end of the spacer layer 220 may contact the rear insulating layer 240. The lowermost end of the spacer layer 220 may be at substantially the same vertical level as a bottom surface of the cover insulating layer 230 or a top surface of the rear insulating layer 240. The uppermost end of the spacer layer 220 may be at the first vertical level LV1. The spacer layer 220 may have a spacer height H. In an X-Z cross section formed by the first horizontal direction (the X direction) and the vertical direction (the Z direction) and passing through the center of the rear contact plug 250 in a plan view, that is, a vertical cross section extending in the first horizontal direction (the X direction) and passing through the center of the rear contact plug 250 in a plan view and a Y-Z cross section formed by the second horizontal direction (the Y direction) and the vertical direction (the Z direction) and passing through the center of the rear contact plug 250 in a plan view, that is, a vertical cross section extending in the second horizontal direction (the Y direction) and passing through the center of the rear contact plug 250 in a plan view, a spacer height H of a portion of the spacer layer 220 surrounding the rear contact plug 250 may be substantially the same.

Referring to FIGS. 1 to 26B together, the integrated circuit device 1 according to embodiments of the present inventive concept includes the rear contact plug 250 surrounded by the spacer layer 220 and connected to the source/drain region 160. The spacer layer 220 is formed to surround the placeholder structure PH aligned with the source/drain region 160 in the vertical direction (the Z direction), and the rear contact plug 250 is formed to fill a space defined by the spacer layer 220. Accordingly, the rear contact plug 250 may be aligned with the source/drain region 160 in the vertical direction (the Z direction). Because the spacer layer 220 surrounds the rear contact plug 250, structural stability of the rear contact plug 250 may be increased.

Therefore, because the integrated circuit device 1 according to embodiments of the inventive concept includes the rear contact plug 250 that is aligned with the source/drain region 160 in the vertical direction (the Z direction) and that is connected to the source/drain region 160, a power delivery network (PDN) capable of performing reliable power delivery may be provided in the integrated circuit device 1.

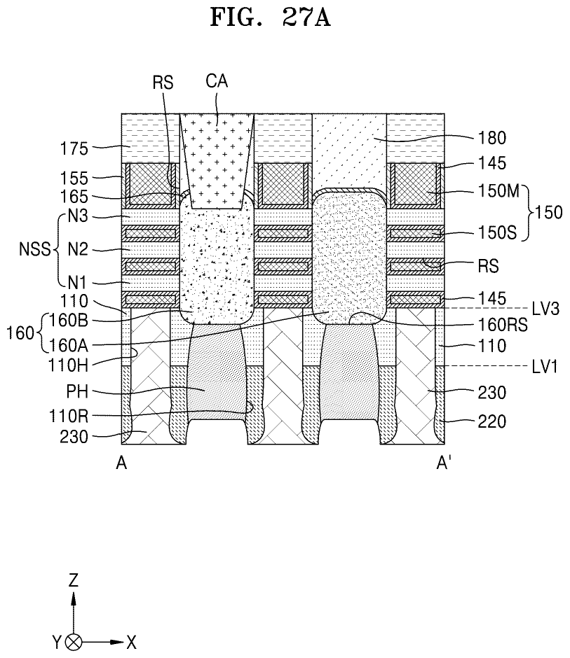

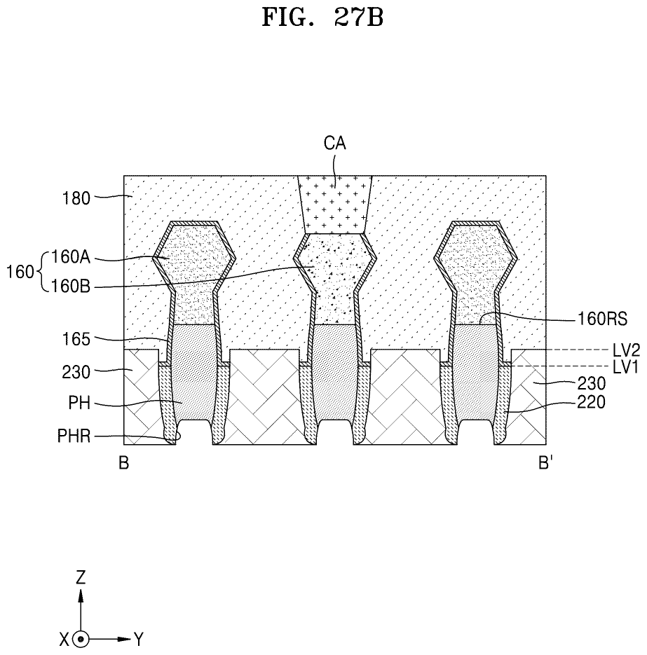

FIGS. 27A to 29B are cross-sectional views illustrating a method of manufacturing an integrated circuit device according to embodiments of the present inventive concept. Specifically, FIGS. 27A, 28A, and 29A are cross-sectional views taken along the line A-A′ of FIG. 1, and FIGS. 27B, 28B, and 29B are cross-sectional views taken along the line B-B′ of FIG. 1.

Referring to FIGS. 21A, 21B, 27A, and 27B together, the hard mask layer 210 may be removed to expose the bottom surface of the placeholder structure PH.

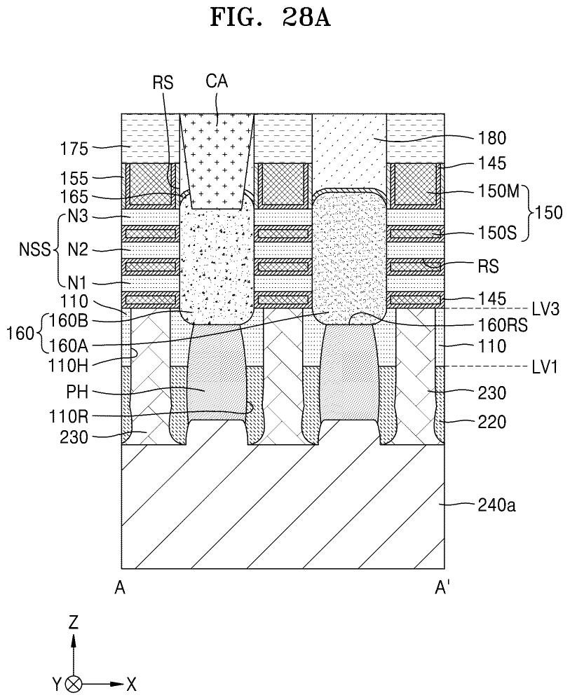

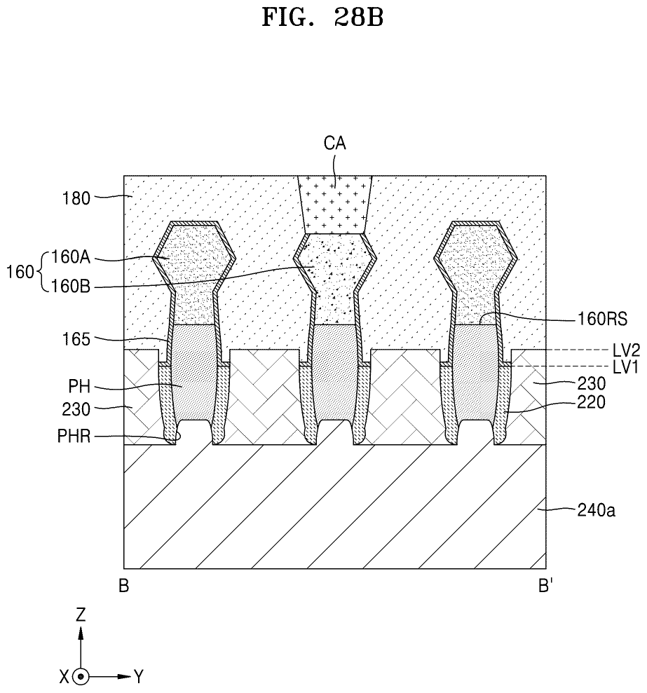

Referring to FIGS. 28A and 28B together, a rear insulating layer 240a is formed to cover a bottom of the cover insulating layer 230. The rear insulating layer 240a may fill a space from which the hard mask layer 210 illustrated in FIGS. 21A and 21B is removed. The rear insulating layer 240a may include oxide. For example, the rear insulating layer 240a may include silicon oxide. The rear insulating layer 240a may have a protrusion filling the space from which the hard mask layer 210 illustrated in FIGS. 21A and 21B is removed. The protrusion of the rear insulating layer 240a may protrude upward toward the placeholder structure PH to contact the placeholder structure PH and may be surrounded by the spacer layer 220. Because the rear insulating layer 240a includes the protrusion surrounded by the spacer layer 220, bonding force with an upper structure, for example, the cover insulating layer 230 and the spacer layer 220 may increase.

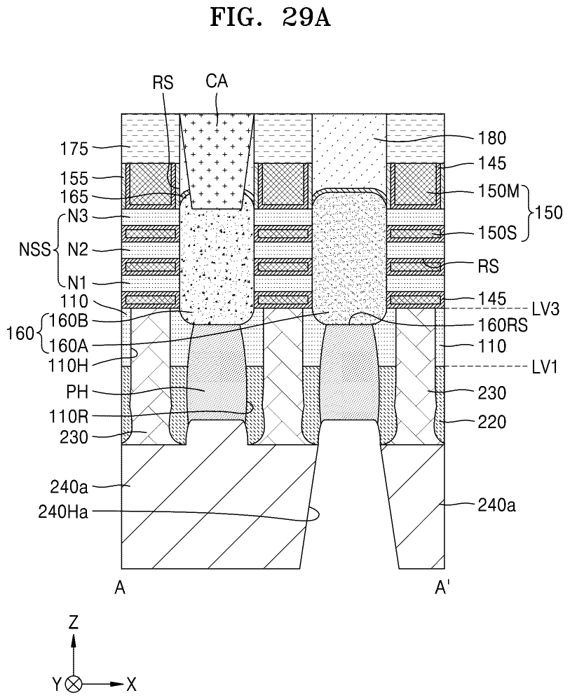

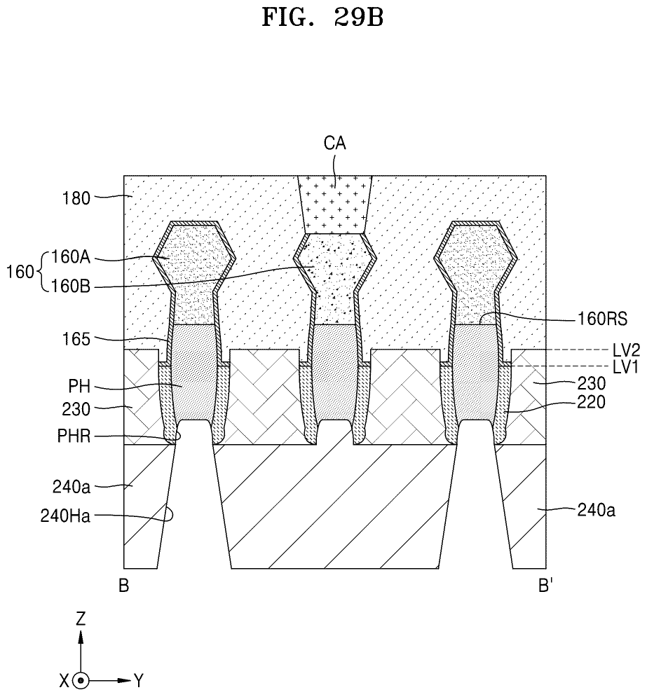

Referring to FIGS. 29A and 29B together, a part of the rear insulating layer 240a is removed to form a rear through hole 240Ha passing through the rear insulating layer 240a. The placeholder structure PH may be exposed in the rear through hole 240Ha. The rear through hole 240Ha might not overlap the source/drain region 160 that is connected to the contact plug CA in the vertical direction (the Z direction), but may overlap the source/drain region 160 that is not connected to the contact plug CA. In embodiments of the present inventive concept, the placeholder structure PH exposed in the rear through hole 240Ha may be positioned under the source region 160A. For example, the rear through hole 240Ha may overlap the source region 160A in the vertical direction (the Z direction), but might not overlap the drain region 160B.

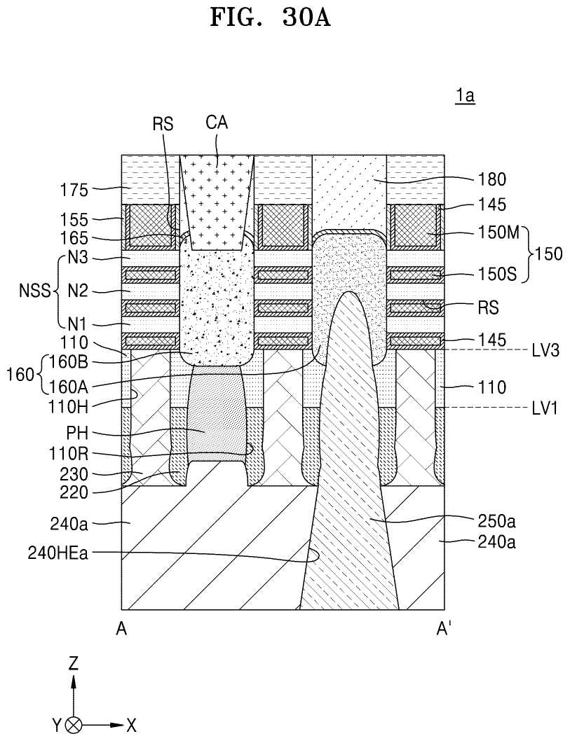

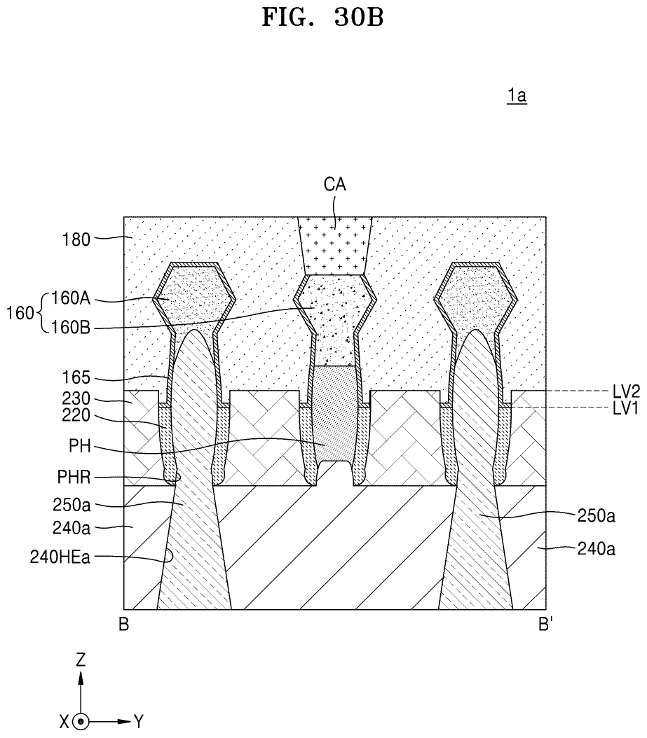

FIGS. 30A and 30B are cross-sectional views illustrating an integrated circuit device 1a according to embodiments of the present inventive concept. Specifically, FIG. 30A is a cross-sectional view taken along the line A-A′ of FIG. 1, and FIG. 30B is a cross-sectional view taken along the line B-B′ of FIG. 1.

Referring to FIGS. 30A and 30B together, in a manner similar to that described with reference to FIGS. 24A to 26B, an extended through hole 240HEa and a rear contact plug 250a filling the extended through hole 240HEa are formed to form the integrated circuit element 1a.

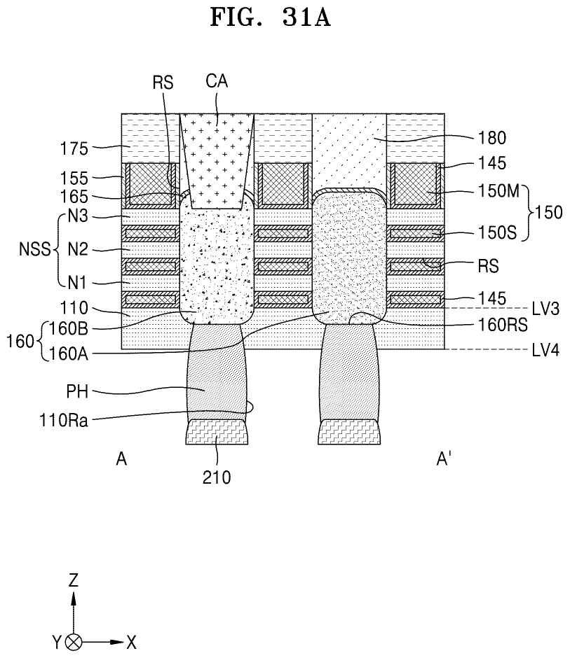

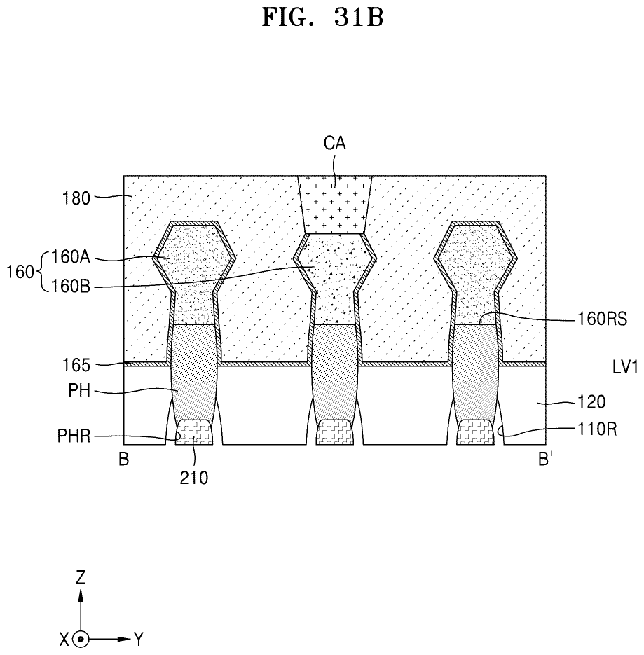

FIGS. 31A and 31B are cross-sectional views illustrating a method of manufacturing an integrated circuit device according to embodiments of the present inventive concept. Specifically, FIG. 31A is a cross-sectional view taken along the line A-A′ of FIG. 1, and FIG. 31B is a cross-sectional view taken along the line B-B′ of FIG. 1.

Referring to FIGS. 31A and 31B together, the lower portion of the substrate 110 illustrated in FIG. 14A is partially removed to form a substrate recess 110Ra. The side surface of the hard mask layer 210 and a part of the side surface of the placeholder structure PH may be exposed to the substrate recess 110Ra. The substrate recess 110Ra may be limited by the bottom surface of the substrate 110, the side surface of the hard mask layer 210, and the side surface of the placeholder structure PH. In embodiments of the present inventive concept, after partially removing the lower portion of the substrate 110 to form the substrate recess 110Ra, the bottom surface of the substrate 110 may be at a fourth vertical level LV4 higher than the first vertical level LV1.

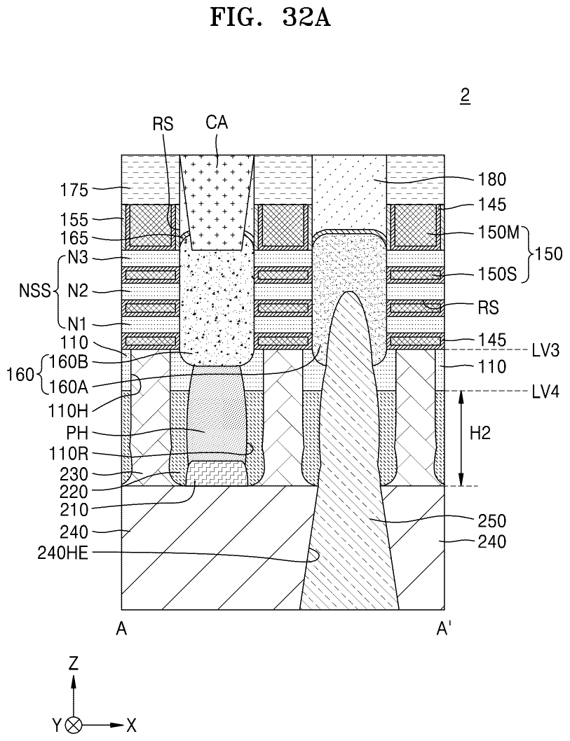

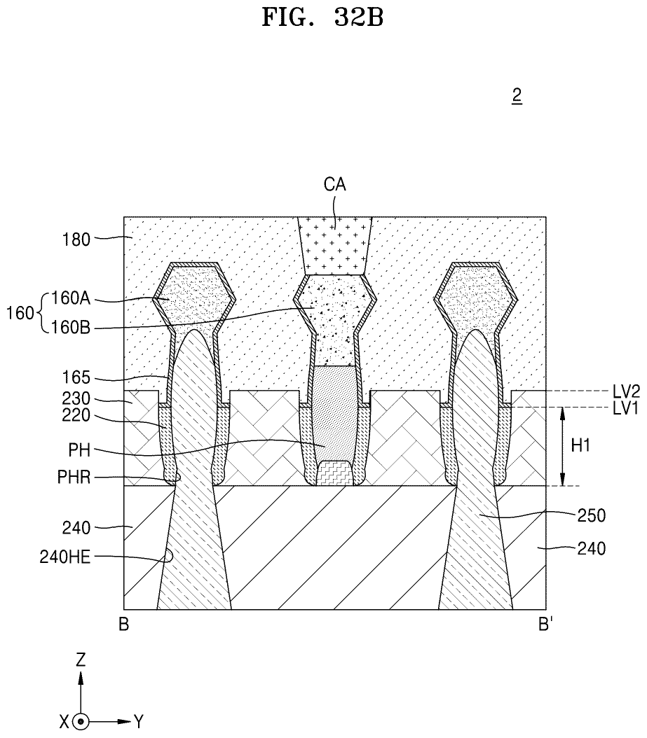

FIGS. 32A and 32B are cross-sectional views illustrating an integrated circuit device 2 according to embodiments of the present inventive concept. Specifically, FIG. 32A is a cross-sectional view taken along the line A-A′ of FIG. 1, and FIG. 32B is a cross-sectional view taken along the line B-B′ of FIG. 1.

Referring to FIGS. 32A and 32B together, the integrated circuit device 2 is formed in a manner similar to that described with reference to FIGS. 16A to 26B.

The uppermost end of the spacer layer 220 may be at the fourth vertical level LV4. In a Y-Z cross section formed by the second horizontal direction (the Y direction) and the vertical direction (the Z direction) and passing through the center of the rear contact plug 250 in a plan view, that is, a vertical cross section extending in the second horizontal direction (the Y direction) and passing through the center of the rear contact plug 250 in a plan view, the uppermost end of the portion of the spacer layer 220 surrounding the rear contact plug 250 may be at the first vertical level LV1 and may have a first spacer height H1. In the X-Z cross section formed by the first horizontal direction (the X direction) and the vertical direction (the Z direction) and passing through the center of the rear contact plug 250 in a plan view, that is, the vertical cross section extending in the first horizontal direction (the X direction) and passing through the center of the rear contact plug 250 in a plan view, the uppermost end of the portion of the spacer layer 220 surrounding the rear contact plug 250 may be at the fourth vertical level LV4 higher than the first vertical level LV1 and may have a second spacer height H2 that is greater than the first spacer height H1.

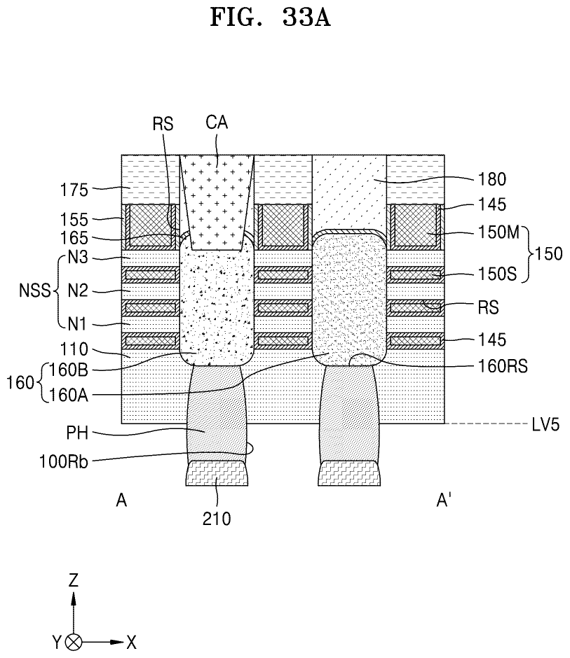

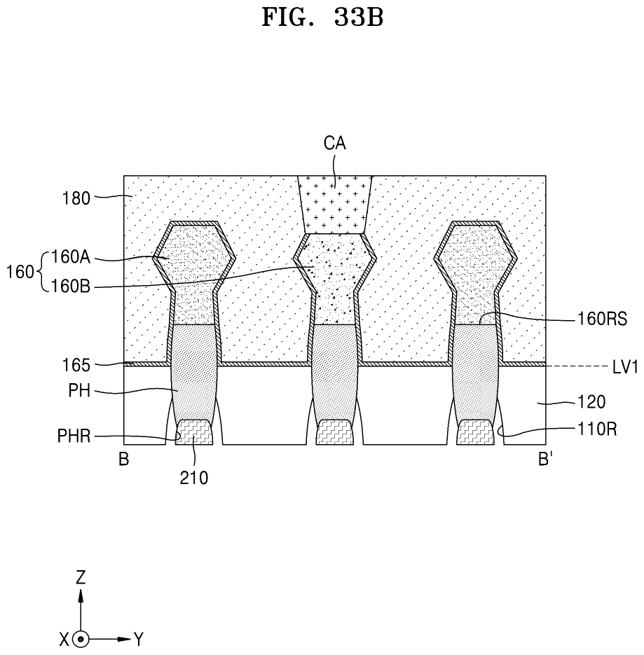

FIGS. 33A and 33B are cross-sectional views illustrating a method of manufacturing an integrated circuit device according to embodiments of the present inventive concept. Specifically, FIG. 33A is a cross-sectional view taken along the line A-A′ of FIG. 1, and FIG. 33B is a cross-sectional view taken along the line B-B′ of FIG. 1.

Referring to FIGS. 33A and 33B together, the lower portion of the substrate 110 illustrated in FIG. 14A is partially removed to form a substrate recess 110Rb. The side surface of the hard mask layer 210 and a part of the side surface of the placeholder structure PH may be exposed to the substrate recess 110Rb. The substrate recess 110Rb may be limited by the bottom surface of the substrate 110, the side surface of the hard mask layer 210, and the side surface of the placeholder structure PH. In embodiments of the present inventive concept, after partially removing the lower portion of the substrate 110 to form the substrate recess 110Rb, the bottom surface of the substrate 110 may be at a fifth vertical level LV5 that is lower than the first vertical level LV1.

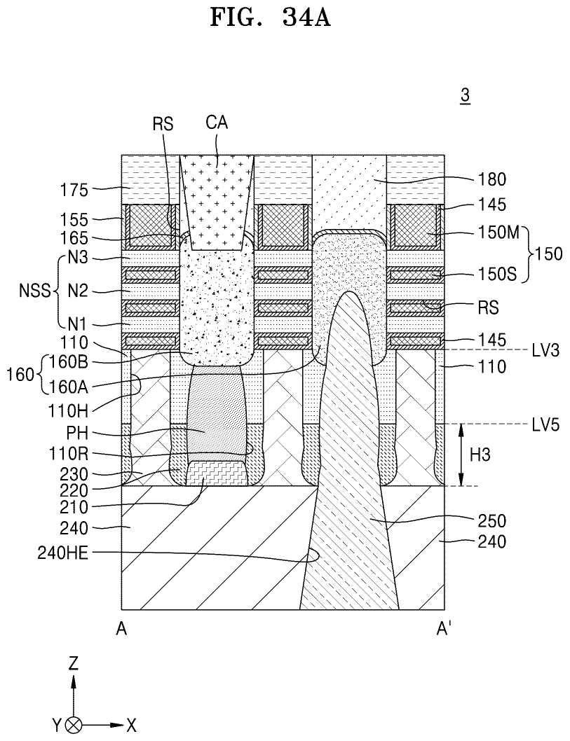

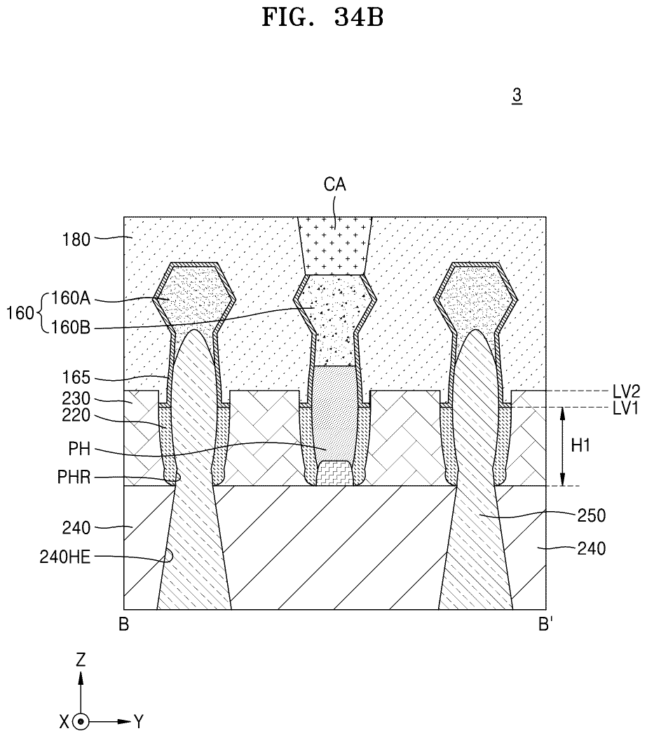

FIGS. 34A and 34B are cross-sectional views illustrating an integrated circuit device 3 according to embodiments of the present inventive concept. Specifically, FIG. 34A is a cross-sectional view taken along the line A-A′ of FIG. 1, and FIG. 34B is a cross-sectional view taken along the line B-B′ of FIG. 1.

Referring to FIGS. 34A and 34B together, the integrated circuit device 3 is formed in a manner similar to that described with reference to FIGS. 16A to 26B.

The uppermost end of the spacer layer 220 may be at the first vertical level LV1. In the Y-Z cross section formed by the second horizontal direction (the Y direction) and the vertical direction (the Z direction) and passing through the center of the rear contact plug 250 in a plan view, that is, the vertical cross section extending in the second horizontal direction (the Y direction) and passing through the center of the rear contact plug 250 in a plan view, the uppermost end of the portion of the spacer layer 220 surrounding the rear contact plug 250 may be at the first vertical level LVI and may have the first spacer height H1. In the X-Z cross section formed by the first horizontal direction (the X direction) and the vertical direction (the Z direction) and passing through the center of the rear contact plug 250 in a plan view, that is, the vertical cross section extending in the first horizontal direction (the X direction) and passing through the center of the rear contact plug 250 in a plan view, the uppermost end of the portion of the spacer layer 220 surrounding the rear contact plug 250 may be at a fifth vertical level LV5 that is lower than the first vertical level LV1 and may have a third spacer height H3 that is less than the first spacer height H1.

Although not separately illustrated, the integrated circuit device 2 illustrated in FIGS. 32A and 32B and the integrated circuit device 3 illustrated in FIGS. 34A and 34B may also include the rear insulating layer 240a included in the integrated circuit device 1a illustrated in FIGS. 30A and 30B instead of the hard mask layer 210 and the rear insulating layer 240.

While the present inventive concept has been described with reference to embodiments thereof, it will be understood by those of ordinary skill in the art that various changes in form and details may be made thereto without departing from the spirit and scope of the present inventive concept.

What is claimed is:

1. An integrated circuit device comprising:
a rear insulating layer;
a nanosheet stacked structure arranged on the rear insulating layer and including a plurality of nanosheets;
a pair of source/drain regions positioned on sides of the nanosheet stacked structure in a first horizontal direction;
a gate electrode extending in a second horizontal direction intersecting the first horizontal direction, on the nanosheet stacked structure;
a contact plug connected to at least one of the pair of source/drain regions;
a rear contact plug passing through the rear insulating layer and connected to at least one of the pair of source/drain regions; and
a spacer layer including a contact spacer layer surrounding part of a side surface of the rear contact plug.

2. The integrated circuit device of claim 1, wherein an uppermost end of the spacer layer is at a vertical level lower than a lowermost end of the pair of source/drain regions.

3. The integrated circuit device of claim 2, wherein an uppermost end of the spacer layer in a vertical cross section extending in the first horizontal direction and passing through a center of the rear contact plug in a plan view is at a same vertical level as an uppermost end of the spacer layer in a vertical cross section extending in the second horizontal direction in a plan view.

4. The integrated circuit device of claim 2, wherein an uppermost end of the spacer layer in a vertical cross section extending in the first horizontal direction and passing through a center of the rear contact plug in a plan view is at a vertical level that is higher than an uppermost end of the spacer layer in a vertical cross section extending in the second horizontal direction in a plan view.

5. The integrated circuit device of claim 2, wherein an uppermost end of the spacer layer in a vertical cross section extending in the first horizontal direction and passing through a center of the rear contact plug in a plan view is at a vertical level that is lower than an uppermost end of the spacer layer in a vertical cross section extending in the second horizontal direction in a plan view.

6. The integrated circuit device of claim 1, wherein a lowermost end of the spacer layer is at a same vertical level as a bottom surface of a cover insulating layer.

7. The integrated circuit device of claim 1, wherein the pair of source/drain regions comprise a source region and a drain region, wherein the contact plug is connected to the drain region, and
wherein the rear contact plug is connected to the source region.

8. The integrated circuit device of claim 7, further comprising a placeholder structure connected to the drain region, wherein the spacer layer further comprises a placeholder spacer layer surrounding part of a side surface of the placeholder structure.

9. The integrated circuit device of claim 1,
wherein an uppermost end of the spacer layer is at a vertical level that is lower than an uppermost end of the rear contact plug, and a lowermost end of the spacer layer is at a vertical level that is higher than a lowermost end of the rear contact plug.

10. An integrated circuit device comprising:
a nanosheet stacked structure including a plurality of nanosheets;
a pair of source/drain regions connected to ends of each of the plurality of nanosheets in a first horizontal direction;
a gate electrode extending in a second horizontal direction intersecting the first horizontal direction, on the nanosheet stacked structure;
an inter-gate insulating layer at least partially surrounding the gate electrode and the pair of source/drain regions;
a contact plug connected to one of the pair of source/drain regions through the inter-gate insulating layer;
an etch stop layer covering surfaces of the pair of source/drain regions and a bottom surface of the inter-gate insulating layer;
a cover insulating layer covering the etch stop layer and the inter-gate insulating layer;
a rear insulating layer covering the cover insulating layer;
a rear contact plug passing through the rear insulating layer and the cover insulating layer and connected to the other of the pair of source/drain regions; and
a spacer layer including a contact spacer layer that surrounds part of a side surface of the rear contact plug and is located between the cover insulating layer and the rear contact plug.

11. The integrated circuit device of claim 10, wherein a lowermost end of the spacer layer is at a same vertical level as a bottom surface of the cover insulating layer, and
wherein an uppermost end of the spacer layer is at a vertical level that is lower than a lowermost end of the pair of source/drain regions.

12. The integrated circuit device of claim 10, wherein an uppermost end of the spacer layer is in contact with the etch stop layer, and
wherein a lowermost end of the spacer layer is in contact with the rear insulating layer.

13. The integrated circuit device of claim 10, wherein the rear contact plug extends into the other of the pair of source/drain regions.

14. The integrated circuit device of claim 10, wherein the rear contact plug and the other of the pair of source/drain regions are aligned with each other in a vertical direction, and
wherein, in a portion in which the other of the pair of source/drain regions is in contact with the rear contact plug, a horizontal width of the rear contact plug is less than a horizontal width of the other of the pair of source/drain regions.

15. The integrated circuit device of claim 10, further comprising a placeholder structure passing through the cover insulating layer and connected to the one of the pair of source/drain regions, wherein the spacer layer further comprises a placeholder spacer layer surrounding part of a side surface of the placeholder structure and located between the cover insulating layer and the placeholder structure.

16. The integrated circuit device of claim 10, wherein a height of the spacer layer in a vertical cross section extending in the first horizontal direction and passing through a center of the rear contact plug in a plan view is greater than a height of the spacer layer in a vertical cross section extending in the second horizontal direction in a plan view.

17. The integrated circuit device of claim 10, wherein a height of the spacer layer in a vertical cross section extending in the first horizontal direction and passing through a center of the rear contact plug in a plan view is less than a height of the spacer layer in a vertical cross section extending in the second horizontal direction in a plan view.

18. An integrated circuit device comprising:
a nanosheet stacked structure including a plurality of nanosheets;
a pair of source/drain regions including a source region and a drain region, wherein the source region and the drain region are connected to ends of the plurality of nanosheets in a first horizontal direction;
a gate electrode extending in a second horizontal direction intersecting the first horizontal direction, on the nanosheet stacked structure;
an inter-gate insulating layer at least partially surrounding the gate electrode and the pair of source/drain regions;
an etch stop layer covering surfaces of the pair of source/drain regions and a bottom surface of the inter-gate insulating layer;
a cover insulating layer covering the etch stop layer and the inter-gate insulating layer;
a rear insulating layer disposed below the cover insulating layer;
a rear contact plug passing through the rear insulating layer and the cover insulating layer and connected to the source region;
a contact plug passing through the inter-gate insulating layer and the etch stop layer and connected to the drain region;
a placeholder structure passing through the cover insulating layer and connected to the drain region; and
a spacer layer including a contact spacer layer and a placeholder spacer layer, wherein the contact spacer layer surrounds part of a side surface of the rear contact plug and is located between the cover insulating layer and the rear contact plug, and the placeholder spacer layer surrounds part of a side surface of the placeholder structure and is located between the cover insulating layer and the placeholder structure.

19. The integrated circuit device of claim 18, further comprising a hard mask layer located between the placeholder structure and the rear insulating layer, wherein the placeholder spacer layer surrounds a side surface of the hard mask layer.

20. The integrated circuit device of claim 18, wherein a bottom surface of the placeholder structure is at a vertical level that is higher than a lowermost end of the placeholder spacer layer, and
wherein the rear insulating layer has a protrusion protruding upward toward the placeholder structure and is surrounded by the placeholder spacer layer.
